(19) United States
(12) Patent Application Publication
(10) Pub. No.: US 2024/0105897 A1
(43) Pub. Date: Mar. 28, 2024

(54) DISPLAY DEVICE, METHOD OF MANUFACTURING THE SAME AND TILED DISPLAY DEVICE INCLUDING THE SAME

(71) Applicant: Samsung Display Co., LTD., Yongin-si (KR)

(72) Inventors: Se Hun CHOI, Yongin-si (KR); Dong Sung LEE, Yongin-si (KR); Mi Sun KIM, Yongin-si (KR); Byung Hoon KIM, Yongin-si (KR); Tae Oh KIM, Yongin-si (KR)

(73) Assignee: Samsung Display Co., LTD., Yongin-si (KR)

(21) Appl. No.: 18/356,436

(22) Filed: Jul. 21, 2023

(30) Foreign Application Priority Data
Sep. 26, 2022 (KR) 10-2022-0121572

(51) Int. Cl. H01L 33/62; H01L 25/075

(52) U.S. Cl. CPC H01L 33/62; H01L 25/0753; H01L 2933/0066

(57) ABSTRACT

A display device comprises a first substrate comprising a first contact hole, a laser absorption layer disposed on the first substrate and containing amorphous silicon, a first barrier insulating layer disposed on the laser absorption layer, fan-out lines disposed in a metal layer on the first barrier insulating layer and comprising pad portions inserted into second contact holes provided in the first barrier insulating layer and the laser absorption layer, a second barrier insulating layer disposed on the metal layer, a second substrate disposed on the second barrier insulating layer, and a display layer disposed on the second substrate. The second substrate is inserted into a third contact hole provided in the second barrier insulating layer, the first barrier insulating layer, and the laser absorption layer disposed between the pad portions.

### CROSS-REFERENCE TO RELATED APPLICATION

This application claims priority to and benefits of Korean Patent Application No. 10-2022-0121572 under 35 U.S.C. § 119, filed on Sep. 26, 2022, in the Korean Intellectual Property Office (KIPO), the entire contents of which are incorporated herein by reference.

### BACKGROUND

### 1. Technical Field

The disclosure relates to a display device, a method of manufacturing the same and a tiled display device including the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device, and an organic light emitting display device. Among the flat panel display devices, in the light emitting display device, since each of pixels of a display panel includes a light emitting element capable of emitting light by itself, an image can be displayed without a backlight unit providing light to the display panel.

When the display device is manufactured in a large size, a defect rate of the light emitting element may increase due to an increase in the number of pixels, thereby deteriorating productivity or reliability of the display device. To solve this problem, in a tiled display device, a large-sized screen may be implemented by connecting display devices having a relatively small size. The tiled display device may include a boundary portion called a seam between the display devices, due to a non-display area or a bezel area of each of the display devices adjacent to each other. In case that a single image is displayed on the entire screen, the boundary portion between the display devices gives a sense of disconnection over the entire screen, thereby reducing a sense of immersion in the image.

### SUMMARY

Aspects of the disclosure provide a display device capable of preventing damage to a metal layer or peeling off of a second substrate in an etching process of a first substrate and insulating adjacent pad portions, a method of manufacturing the same, and a tiled display device including the same.

Aspects of the disclosure also provide a tiled display device capable of removing a sense of disconnection between display devices and improving a sense of immersion in an image, by preventing the recognition of boundary portions or non-display areas between the display devices.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, a display device comprises a first substrate comprising a first contact hole, a laser absorption layer disposed on the first substrate and containing amorphous silicon, a first barrier insulating layer disposed on the laser absorption layer, fan-out lines disposed in a metal layer on the first barrier insulating layer and comprising pad portions inserted into second contact holes provided in the first barrier insulating layer and the laser absorption layer, a second barrier insulating layer disposed on the metal layer, a second substrate disposed on the second barrier insulating layer, and a display layer disposed on the second substrate. The second substrate is inserted into a third contact hole provided in the second barrier insulating layer, the first barrier insulating layer, and the laser absorption layer between the pad portions.

The laser absorption layer disposed between adjacent pad portions among the pad portions may be spaced apart from an adjacent laser absorption layer with the second substrate disposed between the laser absorption layer and the adjacent laser absorption layer.

The display device may further comprise a flexible film disposed under the first substrate and inserted into the first contact hole to be electrically connected to the pad portions.

The display device may further comprise a connection film inserted into the first contact hole to electrically connect the pad portions to the flexible film.

The second substrate may be inserted into the third contact hole to face the connection film.

The display device may further comprise a display driver disposed on the flexible film to supply at least one of a data voltage, a power voltage, and a gate signal.

The second substrate may comprise an etched portion recessed from a surface of the laser absorption layer.

A depth of the etched portion may be greater than a sum of thicknesses of the laser absorption layer, the first and second barrier insulating layers, and the pad portion.

The laser absorption layer disposed between adjacent pad portions among the pad portions may be spaced apart from an adjacent laser absorption layer with the etched portion disposed between the laser absorption layer and the adjacent laser absorption layer.

The display layer may comprise a display area having pixels and a non-display area surrounding the display area. The pad portions and the third contact hole may overlap the display area in a plan view.

The display device may further comprise a third barrier insulating layer disposed between the second substrate and the display layer, and a third substrate disposed between the third barrier insulating layer and the display layer.

According to an embodiment of the disclosure, a display device comprises a first substrate comprising a first contact hole, a laser absorption layer disposed on the first substrate and containing amorphous silicon, a first barrier insulating layer disposed on the laser absorption layer, fan-out lines disposed in a metal layer on the first barrier insulating layer and comprising pad portions inserted into second contact holes provided in the first barrier insulating layer and the laser absorption layer, a second barrier insulating layer disposed on the metal layer, a third contact hole provided in the second barrier insulating layer, the first barrier insulating layer, and the laser absorption layer disposed between the pad portions, a second substrate disposed on the second barrier insulating layer, and a display layer disposed on the second substrate. The second substrate comprises an etched portion recessed from a surface of the laser absorption layer.

Adjacent pad portions among the pad portions may be spaced apart from each other with the etched portion disposed between the adjacent pad portions.

Side surfaces of adjacent pad portions among the pad portions may be exposed by the third contact hole.

The third contact hole has an undercut structure in which an upper area of the third contact hole may be greater than a lower area of the third contact hole.

According to an embodiment of the disclosure, a method of manufacturing a display device comprises providing a first substrate, forming a laser absorption layer containing amorphous silicon on the first substrate, forming a first barrier insulating layer on the laser absorption layer, forming first contact holes penetrating the first barrier insulating layer and the laser absorption layer, forming fan-out lines disposed on the first barrier insulating layer and comprising pad portions inserted into the first contact holes, forming a second barrier insulating layer on the fan-out lines, forming a second contact hole penetrating the second barrier insulating layer, the first barrier insulating layer, and the laser absorption layer disposed between the pad portions, forming a second substrate on the second barrier insulating layer, exposing the laser absorption layer, the pad portions, and the second substrate by etching the first substrate to form a third contact hole, and inserting a flexible film into the third contact hole to electrically connect the flexible film to the pad portion.

The method may further comprise, after etching the first substrate to form the third contact hole, forming an etched portion by further etching the second substrate.

The forming of the second contact hole may comprise forming the second contact hole to have an undercut structure in which an upper area of the second contact hole is greater than a lower area of the second contact hole.

The method may further comprise, after etching the first substrate to form the third contact hole, forming an etched portion by further etching the second substrate, and exposing side surfaces of adjacent pad portions among the pad portions.

According to an embodiment of the disclosure, a tiled display device comprises display devices each comprising a display area having pixels and a non-display area surrounding the display area, and a bonding member configured to bond the display devices. At least one of the display devices comprises a first substrate comprising a first contact hole, a laser absorption layer disposed on the first substrate and containing amorphous silicon, a first barrier insulating layer disposed on the laser absorption layer, fan-out lines disposed in a metal layer on the first barrier insulating layer and comprising pad portions inserted into second contact holes provided in the first barrier insulating layer and the laser absorption layer, a second barrier insulating layer disposed on the metal layer, a second substrate disposed on the second barrier insulating layer, and a display layer disposed on the second substrate. The second substrate is inserted into a third contact hole provided in the second barrier insulating layer, the first barrier insulating layer, and the laser absorption layer disposed between the pad portions.

In accordance with the display device, the method of manufacturing the same, and the tiled display device including the same according to the embodiments, the second substrate on the first substrate is inserted into the contact hole formed between the adjacent pad portions, so that it is possible to prevent the peeling off of the second substrate in the etching process of the first substrate and also possible to insulate the adjacent pad portions.

In accordance with the display device, the method of manufacturing the same, and the tiled display device including the same according to the embodiments, the area of the non-display area of the display device may be minimized by electrically connecting a display driver disposed under a substrate to a fan-out line disposed on the substrate. Accordingly, in the tiled display device, by minimizing the gap formed between the display devices, it is possible to prevent a user from recognizing the boundary portions or the non-display areas formed between the display devices.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a tiled display device according to an embodiment;

FIG. 2 is a schematic cross-sectional view taken along line I-I′ of FIG. 1;

FIG. 3 is a schematic bottom view illustrating a display device according to an embodiment;

FIG. 4 is a schematic enlarged bottom view illustrating a part of a display device according to an embodiment;

FIG. 5 is an example of a schematic cross-sectional view taken along line III-III′ of FIG. 4;

FIG. 6 is a schematic diagram illustrating a pad portion, a fan-out line, a sensing line, and a data line in a display device according to an embodiment;

FIG. 7 is a schematic diagram illustrating a pad portion, a power connection line, a high potential line, and a horizontal voltage line in a display device according to an embodiment;

FIG. 8 is a schematic diagram illustrating a pad portion, a power connection line, a low potential line, and a vertical voltage line in a display device according to an embodiment;

FIG. 9 is a schematic diagram illustrating a pad portion, a fan-out line, and a gate line in a display device according to an embodiment;

FIG. 10 is a schematic block diagram illustrating pixels and lines in a display device according to an embodiment;

FIG. 11 is a schematic diagram of an equivalent circuit illustrating the pixel of FIG. 10;

FIG. 12 is a schematic cross-sectional view taken along line II-IT of FIG. 1;

FIGS. 13 to 19 are schematic cross-sectional views illustrating a manufacturing process of a display device according to an embodiment;

FIG. 20 is another example of a schematic cross-sectional view taken along line III-III′ of FIG. 4;

FIGS. 21 to 24 are schematic cross-sectional views illustrating a manufacturing process of a display device according to another embodiment;

FIG. 25 is another example of a schematic cross-sectional view taken along line III-III′ of FIG. 4; and

FIGS. 26 to 32 are schematic cross-sectional views illustrating a manufacturing process of a display device according to another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

The term “and/or” includes all combinations of one or more of which associated configurations may define. For example, “A and/or B” may be understood to mean “A, B, or A and B.” For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Although the terms “first”, “second”, and the like may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

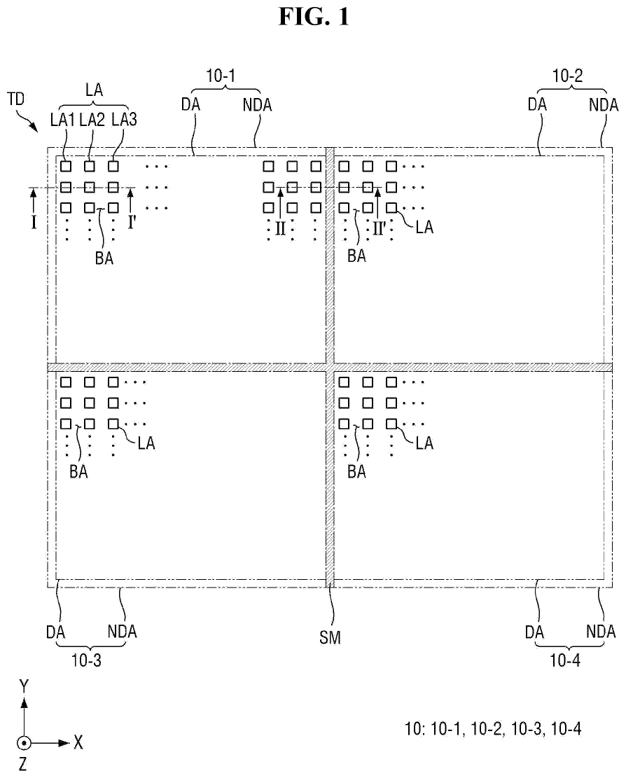

FIG. 1 is a schematic plan view illustrating a tiled display device according to an embodiment.

Referring to FIG. 1, a tiled display device TD may include display devices 10. The display devices 10 may be arranged in a grid form, but are not limited thereto. The display devices 10 may be connected in a first direction (X-axis direction) or a second direction (Y-axis direction), and the tiled display device TD may have a particular shape. For example, the display devices 10 may have a same size, but are not limited thereto. For another example, the display devices 10 may have different sizes.

The tiled display device TD may include first to fourth display devices 10-1 to 10-4. The number and connection relationship of the display devices 10 are not limited to the embodiment of FIG. 1. The number of the display devices 10 may be determined according to the size of each of the display devices 10 and the tiled display device TD.

Each of the display devices 10 may have a rectangular shape including long sides and short sides. The display devices 10 may be arranged such that the long sides or the short sides thereof are connected to each other. Some of the display devices 10 may be disposed at an edge of the tiled display device TD to form a side of the tiled display device TD. Some others of the display devices 10 may be disposed at corners of the tiled display device TD to form two adjacent sides of the tiled display device TD. Yet some others of the display devices 10 may be disposed on the inner side of the tiled display device TD, and may be surrounded by other display devices 10.

Each of the display devices 10 may include a display area DA and a non-display area NDA. The display area DA may include pixels to display an image. Each of the pixels may include an organic light emitting diode (OLED) having an organic light emitting layer, a quantum dot light emitting diode (LED) including a quantum dot light emitting layer, a micro LED, or an inorganic LED having an inorganic semiconductor. In the following, an embodiment where each of the pixels includes an inorganic light emitting diode will be mainly described, but the disclosure is not limited thereto. The non-display area NDA may be disposed around the display area DA to surround the display area DA, and may not display an image.

The display device 10 may include pixels arranged along rows and columns in the display area DA. Each of the pixels may include an emission area LA defined by a pixel defining layer or bank, and may emit light having a peak wavelength (e.g., a predetermined or selectable peak wavelength) through the emission area LA. For example, the display area DA of the display device 10 may include first to third emission areas LA1, LA2, and LA3. Each of the first to third emission areas LA1, LA2, and LA3 may be an area in which light generated from a light emitting element of the display device 10 is emitted to an outside of the display device 10.

The first to third emission areas LA1, LA2, and LA3 may emit light having a peak wavelength to the outside of the display device 10. The first emission area LA1 may emit light of a first color, the second emission area LA2 may emit light of a second color, and the third emission area LA3 may emit light of a third color. For example, the first color light may be red light having a peak wavelength in a range from about 610 nm to about 650 nm, the second color light may be green light having a peak wavelength in a range from about 510 nm to about 550 nm, and the third color light may be blue light having a peak wavelength in a range from about 440 nm to about 480 nm, but the disclosure is not limited thereto.

The first to third emission areas LA1, LA2, and LA3 may be sequentially arranged repetitively in the first direction (X-axis direction) in the display area DA. For example, the size of the third emission area LA3 may be larger than that of the first emission area LA1, and the size of the first emission area LA1 may be larger than that of the second emission area LA2. However, the disclosure is not limited thereto. For another example, the first emission area LA1, the second emission area LA2, and the third emission area LA3 may be substantially a same in size.

The display area DA of the display device 10 may include a light blocking area BA surrounding the emission areas LA. The light blocking area BA may prevent the colored lights emitted from the first to third emission areas LA1, LA2, and LA3 from mixing with one another.

The tiled display device TD may have a planar shape as a whole, but is not limited thereto. The tiled display device TD may have a three-dimensional shape to provide a three-dimensional effect to a user. For example, in case that the tiled display device TD has a three-dimensional shape, at least some of the display devices 10 may have a curved shape. For another example, the display devices 10 may each have a planar shape and may be connected to each other at an angle (e.g., a predetermined or selectable angle), so that the tiled display device TD may have a three-dimensional shape.

The tiled display device TD may include a coupling area SM disposed between display areas DA. The tiled display device TD may be formed by connecting non-display areas NDA of the adjacent display devices 10. The display devices 10 may be connected to each other through a bonding member or an adhesive member disposed in the coupling area SM. The coupling area SM may not include a pad portion or a flexible film attached to the pad portion. Accordingly, the distance between the display areas DA of the display devices 10 may be small enough that the coupling area SM is not recognized by the user. Further, a reflectance of external light of the display areas DA of the display devices 10 may be substantially the same as that of the coupling area SM. Accordingly, in the tiled display device TD, the coupling area SM disposed between the display devices 10 may be prevented from being recognized by the user, thereby reducing a sense of disconnection between the display devices 10 and improving a sense of immersion in an image.

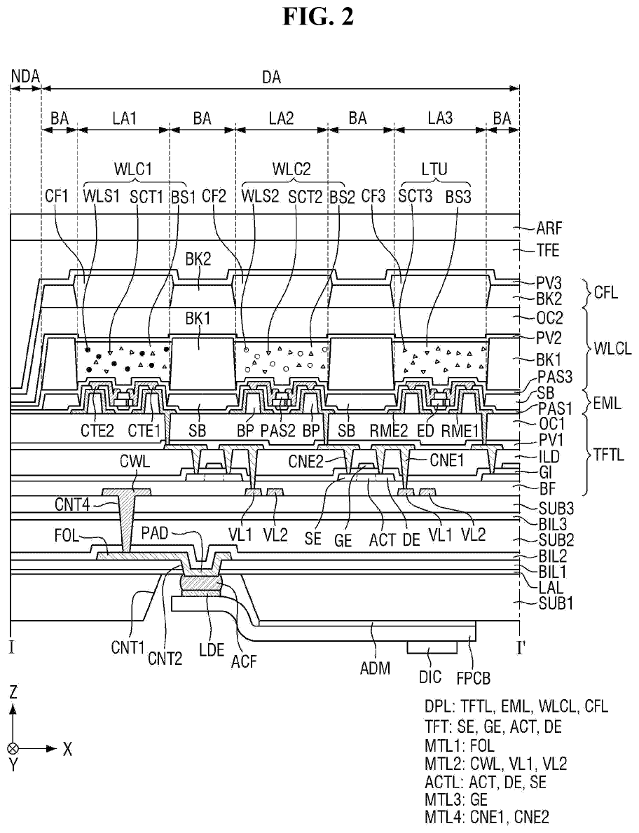

FIG. 2 is a schematic cross-sectional view taken along line I-I′ of FIG. 1.

Referring to FIG. 2, the display area DA of the display device 10 may include the first to third emission areas LA1, LA2, and LA3. Each of the first to third emission areas LA1, LA2, and LA3 may be an area in which light generated from the light emitting element ED of the display device 10 is emitted to the outside of the display device 10.

The display device 10 may include a first substrate SUB1, a laser absorption layer LAL, a first barrier insulating layer BILL a first metal layer MTL1, a second barrier insulating layer BIL2, a second substrate SUB2, a third barrier insulating layer BIL3, a third substrate SUB3, a display layer DPL, an encapsulation layer TFE, an anti-reflection film ARF, a flexible film FPCB, and a display driver DIC.

The first substrate SUB1 may support the display device 10. The first substrate SUB1 may be a base substrate or a base member. The first substrate SUB1 may be a flexible substrate which can be bent, folded or rolled. For example, the first substrate SUB1 may include an insulating material, for example, a polymer resin such as polyimide (PI), but the disclosure is not limited thereto. As another example, the first substrate SUB1 may be a rigid substrate including a glass material.

The first substrate SUB1 may include the first contact hole CNT1. The first contact hole CNT1 may be etched from the bottom surface of the first substrate SUB1 to penetrate the top surface of the first substrate SUB1. For example, the lower width of the first contact hole CNT1 may be greater than the upper width of the first contact hole CNT1. As another example, the lower width of the first contact hole CNT1 may be equal to or less than the upper width of the first contact hole CNT1. During the manufacturing process of the display device 10, a pad portion PAD inserted into a second contact hole CNT2 may be exposed through the first contact hole CNT1, and the pad portion PAD may be electrically connected to a lead electrode LDE of the flexible film FPCB through a connection film ACF inserted into the first contact hole CNT1.

The laser absorption layer LAL may be disposed on the first substrate SUB1. The laser absorption layer LAL may absorb ultraviolet laser in the etching process of the first substrate SUB1 to prevent transmission of the ultraviolet laser. Here, the ultraviolet laser may have, e.g., a wavelength in a range of about 300 nm to about 400 nm or a wavelength in a range of about 340 nm to about 350 nm. The laser absorption layer LAL absorbs the ultraviolet laser in the etching process of the first substrate SUB1, thereby preventing damage to the first metal layer MTL1 or peeling off of the second substrate SUB2. For example, the laser absorption layer LAL may include amorphous silicon (a-Si). A thickness of the laser absorption layer LAL may be, e.g., in a range of about 300 Å to about 1000 Å, or about 500 Å or more in order to effectively block the ultraviolet laser. The thickness of the laser absorption layer LAL may be smaller than a thickness of the first barrier insulating layers BIL1 or the second barrier insulating layer BIL2. The thickness of the laser absorption layer LAL may be smaller than a thickness of a fan-out line FOL or the pad portion PAD.

The first barrier insulating layer BIL1 may be disposed on the laser absorption layer LAL. The first barrier insulating layer BIL1 may include an inorganic layer capable of preventing permeation of air, moisture, or the like. For example, the first barrier insulating layer BIL1 may include at least one of a silicon nitride layer, a silicon oxynitride layer, a silicon oxide layer, a titanium oxide layer, an aluminum oxide layer, an amorphous silicon layer, and the like, but the disclosure is not limited thereto.

The first barrier insulating layer BIL1 and the laser absorption layer LAL may include the second contact hole CNT2. The second contact hole CNT2 may be etched from a top surface of the first barrier insulating layer BIL1 and penetrate to a bottom surface of the laser absorption layer LAL. For example, an upper width of the second contact hole CNT2 may be greater than a lower width of the second contact hole CNT2. In another example, the upper width of the second contact hole CNT2 may be equal to or less than the lower width of the second contact hole CNT2.

The first metal layer MTL1 may be disposed on the first barrier insulating layer BILL The first metal layer MTL1 may include the fan-out line FOL. The first metal layer MTL1 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The pad portion PAD may be integrally formed with (or integral with) the fan-out line FOL and inserted into the second contact hole CNT2. The pad portion PAD may electrically connect the flexible film FPCB to a connection portion CWL. The pad portion PAD may be exposed through the first contact hole CNT1. The pad portion PAD may be electrically connected to the lead electrode LDE of the flexible film FPCB through the connection film ACF. The fan-out line FOL may be electrically connected to a data line, a power line, or a gate line through the connection portion CWL. The data line or the power line may be connected to a drain electrode DE of a thin film transistor TFT. The gate line may be connected to the gate electrode GE of the thin film transistor TFT. Accordingly, the fan-out line FOL may supply a data voltage, a power voltage, or a gate signal received from the display driver DIC of the flexible film FPCB to the thin film transistor TFT of the pixel through the connection portion CWL. The display device 10 includes the fan-out line FOL disposed in the display area DA, so that the area of the non-display area NDA may be minimized.

The second barrier insulating layer BIL2 may be disposed on the first barrier insulating layer BIL1 and the first metal layer MTL1. The second barrier insulating layer BIL2 may include an inorganic layer capable of preventing permeation of air or moisture. For example, the second barrier insulating layer BIL2 may include at least one of a silicon nitride layer, a silicon oxynitride layer, a silicon oxide layer, a titanium oxide layer, an aluminum oxide layer, an amorphous silicon layer, and the like, but the disclosure is not limited thereto.

The second substrate SUB2 may be disposed on the second barrier insulating layer BIL2. The second substrate SUB2 may be a base substrate or a base member. The second substrate SUB2 may be a flexible substrate which can be bent, folded or rolled. For example, the second substrate SUB2 may include an insulating material, for example, a polymer resin such as polyimide (PI), but the disclosure is not limited thereto.

The third barrier insulating layer BIL3 may be disposed on the second substrate SUB2. The third barrier insulating layer BIL3 may include an inorganic layer capable of preventing permeation of air or moisture. For example, the third barrier insulating layer BIL3 may include at least one of a silicon nitride layer, a silicon oxynitride layer, a silicon oxide layer, a titanium oxide layer, an aluminum oxide layer, an amorphous silicon layer, and the like, but the disclosure is not limited thereto.

The third substrate SUB3 may be disposed on the third barrier insulating layer BIL3. The third substrate SUB3 may be a base substrate or a base member. The third substrate SUB3 may be a flexible substrate which can be bent, folded or rolled. For example, the third substrate SUB3 may include an insulating material, for example, a polymer resin such as polyimide (PI), but the disclosure is not limited thereto. As another example, the third substrate SUB3 may be omitted.

The third substrate SUB3, the third barrier insulating layer BIL3, the second substrate SUB2, and the second barrier insulating layer BIL2 may include a fourth contact hole CNT4. The fourth contact hole CNT4 may be etched from the top surface of the third substrate SUB3 to penetrate the bottom surface of the second barrier insulating layer BIL2. For example, the upper width of the fourth contact hole CNT4 may be greater than the lower width of the fourth contact hole CNT4. In another example, the upper width of the fourth contact hole CNT4 may be equal to or less than the lower width of the fourth contact hole CNT4. During the manufacturing process of the display device 10, the top surface of the fan-out line FOL may be exposed through the fourth contact hole CNT4, and the fan-out line FOL may contact the connection portion CWL inserted into the fourth contact hole CNT4.

The display layer DPL may be disposed on the third substrate SUB3. The display layer DPL may include a thin film transistor layer TFTL, a light emitting element layer EML, a wavelength conversion layer WLCL and a color filter layer CFL. The thin film transistor layer TFTL may include a second metal layer MTL2, a buffer layer BF, an active layer ACTL, a gate insulating layer GI, a third metal layer MTL3, an interlayer insulating layer ILD, a fourth metal layer MTL4, a first passivation layer PV1, and a first planarization layer OC1.

The second metal layer MTL2 may be disposed on the third substrate SUB3. The second metal layer MTL2 may include the connection portion CWL and first and second voltage lines VL1 and VL2. The connection portion CWL and the first and second voltage lines VL1 and VL2 may be formed of the same material in the same layer, but the disclosure is not limited thereto. For example, the second metal layer MTL2 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The connection portion CWL may be inserted into the fourth contact hole CNT4 to be connected to the fan-out line FOL. For example, the connection portion CWL may be electrically connected to the data line to supply the data voltage to the thin film transistor TFT. The connection portion CWL may be electrically connected to the power line to supply the power voltage to the thin film transistor TFT. The connection portion CWL may be electrically connected to the gate line to supply the gate signal to the thin film transistor TFT. Accordingly, the connection portion CWL may supply the data voltage, the power voltage, or the gate signal received from the display driver DIC through the fan-out line FOL to the thin film transistor TFT of the pixel.

The first and second voltage lines VL1 and VL2 may extend in the second direction (Y-axis direction) in the display area DA. Each of the first and second voltage lines VL1 and VL2 may be electrically connected to the fan-out line FOL. Each of the first and second voltage lines VL1 and VL2 may be electrically connected to the thin film transistor TFT or the light emitting element ED. For example, each of the first and second voltage lines VL1 and VL2 may be a data line, a high potential line, a low potential line, or a sensing line, but is not limited thereto.

The buffer layer BF may be disposed on the second metal layer MTL2 and the third substrate SUBS. The buffer layer BF may include an inorganic material capable of preventing permeation of air or moisture. For example, the buffer layer BF may include inorganic layers laminated alternately.

The active layer ACTL may be disposed on the buffer layer BF. The active layer ACTL may include a semiconductor region ACT, a drain electrode DE, and a source electrode SE of the thin film transistor TFT. The semiconductor region ACT may overlap the gate electrode GE in a thickness direction (Z-axis direction), and may be insulated from the gate electrode GE by the gate insulating layer GI. The drain electrode DE and the source electrode SE may be provided by making a material of the semiconductor region ACT conductive. The thin film transistor TFT may constitute a pixel circuit of each of the pixels. For example, the thin film transistor TFT may be a switching transistor or a driving transistor of the pixel circuit.

The gate insulating layer GI may be disposed on the active layer ACTL and the buffer layer BF. The gate insulating layer GI may insulate the gate electrode GE from the semiconductor region ACT of the thin film transistor TFT. The gate insulating layer GI may include a contact hole through which each of the first and second connection electrodes CNE1 and CNE2 passes.

The third metal layer MTL3 may be disposed on the gate insulating layer GI. The third metal layer MTL3 may include the gate electrode GE of the thin film transistor TFT. The gate electrode GE may overlap the semiconductor region ACT with the gate insulating layer GI disposed therebetween. The gate electrode GE may receive a gate signal from the gate line. For example, the third metal layer MTL3 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The interlayer insulating layer ILD may be disposed on the third metal layer MTL3 and the gate insulating layer GI. The interlayer insulating layer ILD may insulate the third and fourth metal layers MTL3 and MTL4. The interlayer insulating layer ILD may include a contact hole through which each of the first and second connection electrodes CNE1 and CNE2 passes.

The fourth metal layer MTL4 may be disposed on the interlayer insulating layer ILD. The fourth metal layer MTL4 may include the first and second connection electrodes CNE1 and CNE2. The first and second connection electrodes CNE1 and CNE2 may be formed of the same material in the same layer, but the disclosure is not limited thereto. For example, the fourth metal layer MTL4 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The first connection electrode CNE1 may electrically connect the first voltage line VL1 to the drain electrode DE of the thin film transistor TFT. An end of the first connection electrode CNE1 may contact the first voltage line VL1 of the second metal layer MTL2, and another end of the first connection electrode CNE1 may contact the drain electrode DE of the active layer ACTL.

The second connection electrode CNE2 may electrically connect the source electrode SE of the thin film transistor TFT to a first electrode RME1. An end of the second connection electrode CNE2 may contact the source electrode SE of the active layer ACTL, and another end of the second connection electrode CNE2 may contact the first electrode RME1 of the light emitting element layer EML.

The first passivation layer PV1 may be disposed on the fourth metal layer MTL4 and the interlayer insulating layer ILD. The first passivation layer PV1 may protect the thin film transistor TFT. The first passivation layer PV1 may include a contact hole through which the first electrode RME1 passes.

The first planarization layer OC1 may be disposed on the first passivation layer PV1 to flatten the upper end of the thin film transistor layer TFTL. For example, the first planarization layer OC1 may include a contact hole through which the first electrode RME1 passes. Here, the contact hole of the first planarization layer OC1 may be connected to the contact hole of the first passivation layer PV1. The first planarization layer OC1 may contain an organic insulating material such as polyimide (PI).

The light emitting element layer EML may be disposed on the thin film transistor layer TFTL. The light emitting element layer EML may include a protruding pattern BP, the first electrode RME1, a second electrode RME2, a first insulating layer PAS1, a sub-bank SB, the light emitting element ED, a second insulating layer PAS2, a first contact electrode CTE1, a second contact electrode CTE2, and a third insulating layer PASS.

The protruding pattern BP may be disposed on the first planarization layer OC1. The protruding pattern BP may protrude from the top surface of the first planarization layer OC1. Protruding patterns BP may be disposed in an opening area or the emission area LA of each of the pixels. Light emitting elements ED may be arranged between the protruding patterns BP. The protruding pattern BP may have inclined side surfaces, and the light emitted from the light emitting elements ED may be reflected by the first and second electrodes RME1 and RME2 arranged on the protruding patterns BP. For example, the protruding pattern BP may include an organic insulating material such as polyimide (PI).

The first electrode RME1 may be disposed on the first planarization layer OC1 and the protruding pattern BP. The first electrode RME1 may be disposed on the protruding pattern BP located on a side of the light emitting elements ED. The first electrode RME1 may be disposed on the inclined surfaces of the protruding pattern BP and reflect the light emitted from the light emitting element ED. The first electrode RME1 may be inserted into the contact hole provided in the first planarization layer OC1 and the first passivation layer PV1 and connected to the second connection electrode CNE2. The first electrode RME1 may be electrically connected to an end of the light emitting element ED through the first contact electrode CTE1. For example, the first electrode RME1 may receive a voltage that is proportional to the luminance of the light emitting element ED from the thin film transistor TFT of the pixel.

The second electrode RME2 may be disposed on the first planarization layer OC1 and the protruding pattern BP. The second electrode RME2 may be disposed on the protruding pattern BP located on another side of the light emitting elements ED. The second electrode RME2 may be disposed on the inclined surfaces of the protruding pattern BP and reflect the light emitted from the light emitting element ED. The second electrode RME2 may be electrically connected to another end of the light emitting element ED through the second contact electrode CTE2. For example, the second electrode RME2 may receive a low potential voltage supplied from a low potential line to all the pixels.

The first and second electrodes RME1 and RME2 may contain a conductive material having high reflectivity. For example, the first and second electrodes RME1 and RME2 may contain at least one of aluminum (Al), silver (Ag), copper (Cu), nickel (Ni), lanthanum (La), and the like. For another example, the first and second electrodes RME1 and RME2 may include a material such as indium tin oxide (ITO), indium zinc oxide (IZO), and indium tin zinc oxide (ITZO). In another example, the first and second electrodes RME1 and RME2 may contain layers including a transparent conductive material layer and a metal layer having high reflectivity, or may include a layer containing a transparent conductive material or a metal having high reflectivity. The first and second electrodes RME1 and RME2 may have a stacked structure of ITO/Ag/ITO, ITO/Ag/IZO, ITO/Ag/ITZO/IZO, or the like.

The first insulating layer PAS1 may be disposed on the first planarization layer OC1, and the first and second electrodes RME1 and RME2. The first insulating layer PAS1 may protect and insulate the first electrode RME1 and the second electrode RME2 from each other. The first insulating layer PAS1 may prevent damage caused by direct contact between the light emitting element ED and the first and second electrodes RME1 and RME2 in an alignment process of the light emitting element ED.

The sub-bank SB may be disposed in the light blocking area BA on the first insulating layer PAS1. The sub-bank SB may be disposed at the boundary of the pixels to distinguish the light emitting elements ED of each of the pixels. The sub-bank SB may have a height (e.g., a predetermined or selectable height) and may contain an organic insulating material such as polyimide (PI).

The light emitting elements ED may be arranged on the first insulating layer PAS1. The light emitting elements ED may be arranged in parallel to each other between the first electrode RME1 and the second electrode RME2. The length of the light emitting element ED may be greater than the distance between the first electrode RME1 and the second electrodes RME2. The light emitting element ED may include semiconductor layers, and an end thereof may be defined with respect to the first semiconductor layer, and another end thereof opposite to the an end may be defined with respect to the second semiconductor layer. An end of the light emitting element ED may be disposed on the first electrode RME1, and another end of the light emitting element ED may be disposed on the second electrode RME2. An end of the light emitting element ED may be electrically connected to the first electrode RME1 through the first contact electrode CTE1, and another end of the light emitting element ED may be electrically connected to the second electrode RME2 through the second contact electrode CTE2.

The light emitting element ED may have a micro-meter or nano-meter size, and may be an inorganic light emitting diode including an inorganic material. The light emitting element ED may be aligned between the first electrode RME1 and the second electrode RME2 facing each other by the electric field formed in a specific direction between the first electrode RME1 and the second electrode RME2.

For example, light emitting elements ED may include active layers having the same material and emit light of the same wavelength band or light of the same color. The lights emitted from the first to third emission areas LA1, LA2, and LA3 of the light emitting element layer EML may have the same color. For example, the light emitting elements ED may emit light of a third color or blue light having a peak wavelength in a range of about 440 nm to about 480 nm, but the disclosure is not limited thereto.

The second insulating layer PAS2 may be disposed on the light emitting elements ED. For example, the second insulating layer PAS2 may partially surround the light emitting elements ED and may not cover ends of the light emitting elements ED. The second insulating layer PAS2 may protect the light emitting elements ED, and may fix the light emitting elements ED in the manufacturing process of the display device 10. The second insulating layer PAS2 may fill a space formed between the light emitting element ED and the first insulating layer PAS1.

The first contact electrode CTE1 may be disposed on the first insulating layer PAS1, and may be connected to the first electrode RME1 while being inserted into the contact hole provided in the first insulating layer PAS1. For example, the contact hole of the first insulating layer PAS1 may be disposed on the protruding pattern BP, but the disclosure is not limited thereto. An end of the first contact electrode CTE1 may be connected to the first electrode RME1 on the protruding pattern BP, and another end of the first contact electrode CTE1 may be connected to an end of the light emitting element ED.

The second contact electrode CTE2 may be disposed on the first insulating layer PAS1, and may be connected to the second electrode RME2 while being inserted into the contact hole provided in the first insulating layer PAS1. For example, the contact hole of the first insulating layer PAS1 may be disposed on the protruding pattern BP, but the disclosure is not limited thereto. An end of the second contact electrode CTE2 may be connected to another end of the light emitting element ED, and another end of the second contact electrode CTE2 may be connected to the second electrode RME2 on the protruding pattern BP.

The third insulating layer PAS3 may be disposed on the first and second contact electrodes CTE1 and CTE2, the sub-bank SB, and the first and second insulating layers PAS1 and PAS2. The third insulating layer PAS3 may be disposed at an upper end of the light emitting element layer EML to protect the light emitting element layer EML.

The wavelength conversion layer WLCL may be disposed on the light emitting element layer EML. The wavelength conversion layer WLCL may include a first light blocking member BK1, a first wavelength conversion member WLC1, a second wavelength conversion member WLC2, a light transmission member LTU, a second passivation layer PV2, a second planarization layer OC2, or the like.

The first light blocking member BK1 may be disposed in the light blocking area BA on the third insulating layer PAS3. The first blocking member BK1 may overlap the sub-bank SB in the thickness direction (Z-axis direction). The first light blocking member BK1 may block transmission of light. The first light blocking member BK1 may prevent light infiltration and color mixture between the first to third emission areas LA1, LA2, and LA3, which may improve color reproducibility of the display device 10. The first light blocking member BK1 may be arranged in the form of a grid surrounding the first to third emission areas LA1, LA2, and LA3 in a plan view.

The first wavelength conversion member WLC1 may be disposed in the first emission area LA1 on the third insulating layer PAS3. The first wavelength conversion member WLC1 may be surrounded by the first light blocking member BK1. The first wavelength conversion member WLC1 may change or shift the peak wavelength of the incident light to a first peak wavelength. The first wavelength conversion member WLC1 may include a first based resin BS1, a first scatterer SCT1, and a first wavelength shifter WLS1.

The first base resin BS1 may contain a material having a relatively high light transmittance. The first base resin BS1 may be formed of a transparent organic material. For example, the first base resin BS1 may contain at least one of organic materials such as epoxy resin, acrylic resin, cardo resin, or imide resin.

The first scatterer SCT1 may have a refractive index different from that of the first base resin BS1 and form an optical interface with the first base resin BS1. For example, the first scatterer SCT1 may contain a light scattering material or light scattering particles that scatter at least a part of the transmitted light. For example, the first scatterer SCT1 may contain a metallic oxide such as titanium oxide (TiO₂), zirconium oxide (ZrO₂), aluminum oxide (AL₂O₃), indium oxide (In₂O₃), zinc oxide (ZnO), or tin oxide (SnO₂), or may contain organic particles such as acrylic resin and urethane resin. The first scatterer SCT1 may scatter light in random directions regardless of the incidence direction of the incident light without any substantial change of the peak wavelength of the incident light.

The first wavelength shifter WLS1 may change or shift the peak wavelength of the incident light to a first peak wavelength. For example, the first wavelength shifter WLS1 may convert blue light provided from the display device 10 into red light having a single peak wavelength in a range of about 610 nm to about 650 nm and emit the red light. The first wavelength shifter WLS1 may be a quantum dot, a quantum rod, or a fluorescent substance. The quantum dot may be a particulate material that emits light of a specific color when an electron transitions from a conduction band to a valence band.

A part of the blue light emitted from the light emitting element layer EML may pass through the first wavelength conversion member WLC1 without being converted to red light by the first wavelength shifter WLS1. Among the blue light emitted from the light emitting element layer EML, the light incident on the first color filter CF1 without being converted by the first wavelength conversion member WLC1 may be blocked by the first color filter CF1. The red light produced by the first wavelength conversion member WLC1 converting the blue light emitted from the light emitting element layer EML may pass through the first color filter CF1 to be emitted to the outside. Accordingly, the red light may be emitted through the first emission area LA1.

The second wavelength conversion member WLC2 may be disposed in the second emission area LA2 on the third insulating layer PAS3. The second wavelength conversion member WLC2 may be surrounded by the first light blocking member BK1. The second wavelength conversion member WLC2 may change or shift the peak wavelength of the incident light to a second peak wavelength. The second wavelength conversion member WLC2 may include a second base resin BS2, a second scatterer SCT2, and a second wavelength shifter WLS2.

The second base resin BS2 may contain a material having a relatively high light transmittance. The second base resin BS2 may be formed of a transparent organic material. For example, the second base resin BS2 may be made of the same material as the first base resin BS1, or may be made of the material exemplified in association with the first base resin BS1.

The second scatterer SCT2 may have a refractive index different from that of the second base resin BS2 and form an optical interface with the second base resin BS2. For example, the second scatterer SCT2 may contain a light scattering material or light scattering particles scattering at least a part of the transmitted light. For example, the second scatterer SCT2 may be made of the same material as the first scatterer SCT1, or may be made of the material exemplified in association with the first scatterer SCT1.

The second wavelength shifter WLS2 may change or shift the peak wavelength of the incident light to a second peak wavelength different from the first peak wavelength of the first wavelength shifter WLS1. For example, the second wavelength shifter WLS2 may convert blue light provided from the display device 10 into green light having a single peak wavelength in a range of about 510 nm to about 550 nm and emit the green light. The second wavelength shifter WLS2 may be a quantum dot, a quantum rod, or a fluorescent substance. The second wavelength shifter WLS2 may contain the materials exemplified in association with the first wavelength shifter WLS1. The second wavelength shifter WLS2 may be formed of a quantum dot, a quantum rod, or a fluorescent substance to have a wavelength conversion range different from that of the first wavelength shifter WLS1.

The light transmission member LTU may be disposed in the third emission area LA3 on the third insulating layer PAS3. The light transmission member LTU may be surrounded by the first light blocking member BK1. The light transmission member LTU may allow the incident light to pass therethrough while maintaining the peak wavelength of the light. The light transmission member LTU may include a third base resin BS3 and a third scatterer SCT3.

The third base resin BS3 may contain a material having a relatively high light transmittance. The third base resin BS3 may be formed of a transparent organic material. For example, the third base resin BS3 may be made of the same material as the first base resin BS1 or the second base resin BS2, or may be made of the material exemplified in association with the first base resin BS1.

The third scatterer SCT3 may have a refractive index different from that of the third base resin BS3 and form an optical interface with the third base resin BS3. For example, the third scatterer SCT3 may contain a light scattering material or light scattering particles scattering at least a part of the transmitted light. For example, the third scatterer SCT3 may be formed of the same material as the first scatterer SCT1 or the second scatterer SCT2, or may be made of the material exemplified in association with the first scatterer SCT1.

Since the wavelength conversion layer WLCL is disposed (e.g. be disposed directly) on the third insulating layer PAS3 of the light emitting element layer EML, the display device 10 may not require a separate substrate for the first and second wavelength conversion members WLC1 and WLC2 and the light transmission member LTU. Accordingly, the first and second wavelength conversion members WLC1 and WLC2 and the light transmission member LTU may be readily aligned in the first to third emission areas LA1, LA2, and LA3, correspondingly, and a thickness of the display device 10 may be relatively reduced.

The second passivation layer PV2 may cover the first and second wavelength conversion members WLC1 and WLC2, the light transmission member LTU, and the first light blocking member BK1. For example, the second passivation layer PV2 may seal the first and second wavelength conversion members WLC1 and WLC2 and the light transmission member LTU to prevent the first and second wavelength conversion members WLC1 and WLC2 and the light transmission member LTU from damage or contamination. For example, the second passivation layer PV2 may contain an inorganic material.

The second planarization layer OC2 may be disposed on the second passivation layer PV2 to flatten the upper ends of the first and second wavelength conversion members WLC1 and WLC2 and the light transmission member LTU. For example, the second planarization layer OC2 may contain an organic insulating material such as polyimide (PI).

The color filter layer CFL may be disposed on the wavelength conversion layer WLCL. The color filter layer CFL may include a second light blocking member BK2, first to third color filters CF1, CF2, and CF3, and a third passivation layer PV3.

The second light blocking member BK2 may be disposed in the light blocking area BA on the second planarization layer OC2 of the wavelength conversion layer WLCL. The second blocking member BK2 may overlap the first blocking member BK1 or the sub-bank SB in the thickness direction (Z-axis direction). The second light blocking member BK2 may block transmission of light. The second light blocking member BK2 may prevent light infiltration and color mixture between the first to third emission areas LA1, LA2, and LA3, which may improve color reproducibility of the display device 10. The second light blocking member BK2 may be arranged in the form of a grid surrounding the first to third emission areas LA1, LA2, and LA3 in a plan view.

The first color filter CF1 may be disposed in the first emission area LA1 on the second planarization layer OC2. The first color filter CF1 may be surrounded by the second light blocking member BK2. The first color filter CF1 may overlap the first wavelength conversion member WLC1 in the thickness direction (Z-axis direction). The first color filter CF1 may selectively allow the first color light (e.g., red light) to pass therethrough, and block or absorb the second color light (e.g., green light) and the third color light (e.g., blue light). For example, the first color filter CF1 may be a red color filter and contain a red colorant.

The second color filter CF2 may be disposed in the second emission area LA2 on the second planarization layer OC2. The second color filter CF2 may be surrounded by the second light blocking member BK2. The second color filter CF2 may overlap the second wavelength conversion member WLC2 in the thickness direction (Z-axis direction). The second color filter CF2 may selectively allow the second color light (e.g., green light) to pass therethrough, and block or absorb the first color light (e.g., red light) and the third color light (e.g., blue light). For example, the second color filter CF2 may be a green color filter and contain a green colorant.

The third color filter CF3 may be disposed in the third emission area LA3 on the second planarization layer OC2. The third color filter CF3 may be surrounded by the second light blocking member BK2. The third color filter CF3 may overlap the light transmission member LTU in the thickness direction (Z-axis direction). The third color filter CF3 may selectively allow the third color light (e.g., blue light) to pass therethrough, and block or absorb the first color light (e.g., red light) and the second color light (e.g., green light). For example, the third color filter CF3 may be a blue color filter and contain a blue colorant.

The first to third color filters CF1, CF2, and CF3 may absorb a part of the light coming from the outside of the display device 10 to reduce the reflected light of the external light. Thus, the first to third color filters CF1, CF2, and CF3 can prevent color distortion caused by the reflection of the external light.

Since the first to third color filters CF1, CF2, and CF3 are disposed (e.g. disposed directly) on the second planarization layer OC2 of the wavelength conversion layer WLCL, the display device 10 may not require a separate substrate for the first to third color filters CF1, CF2, and CF3. Therefore, the thickness of the display device 10 may be relatively reduced.

The third passivation layer PV3 may cover the first to third color filters CF1, CF2, and CF3, and the second light blocking member BK2. The third passivation layer PV3 may protect the first to third color filters CF1, CF2, and CF3.

The encapsulation layer TFE may be disposed on the third passivation layer PV3 of the color filter layer CFL. The encapsulation layer TFE may cover the top and side surfaces of the display layer DPL. For example, the encapsulation layer TFE may include at least one inorganic layer to prevent permeation of oxygen or moisture. The encapsulation layer TFE may include at least one organic layer to protect the display device 10 from foreign substances such as dust.

The anti-reflection film ARF may be disposed on the encapsulation layer TFE. The anti-reflection film ARF may prevent reflection of external light, thereby reducing a decrease in visibility due to reflection of external light. The anti-reflection film ARF may protect the top surface of the display device 10. As another example, the anti-reflection film ARF may be omitted. For another example, the anti-reflection film ARF may be replaced with a polarizing film.

The flexible film FPCB may be disposed under the first substrate SUB1. The flexible film FPCB may be disposed on the edge of the bottom surface of the display device 10. The flexible film FPCB may be attached to the bottom surface of the first substrate SUB1 using the adhesive member ADM. The flexible film FPCB may include the lead electrode LDE disposed on the top surface of a side. The lead electrode LDE may be inserted into the first contact hole CNT1 to be electrically connected to the pad portion PAD through the connection film ACF. The flexible film FPCB may support the display driver DIC disposed on the bottom surface on another side. The lead electrode LDE may be electrically connected to the display driver DIC through a lead line (not shown) disposed on the bottom surface of the flexible film FPCB. Another side of the flexible film FPCB may be connected to a source circuit board (not shown) under the first substrate SUB1. The flexible film FPCB may transmit a signal and a voltage of the display driver DIC to the display device 10.

The connection film ACF may attach the lead electrode LDE of the flexible film FPCB to the pad portion PAD. A surface of the connection film ACF may be attached to the pad portion PAD, and another surface of the connection film ACF may be attached to the lead electrode LDE. For example, the connection film ACF may include an anisotropic conductive film. In case that the connection film ACF includes the anisotropic conductive film, the connection film ACF may have conductivity in a region where the pad portion PAD and the lead electrode LDE contact each other, and may electrically connect the flexible film FPCB to the fan-out line FOL.

The display driver DIC may be mounted or disposed on the flexible film FPCB. The display driver DIC may be an integrated circuit (IC). The display driver DIC may convert digital video data into an analog data voltage based on the data control signal received from a timing controller (not shown), and supply the analog data voltage to the data line of the display area DA through the flexible film FPCB. The display driver DIC may supply the power voltage received from a power supply unit (not shown) to the power line of the display area DA through the flexible film FPCB. The display driver DIC may generate gate signals based on the gate control signal, and may sequentially supply the gate signals to the gate lines according to a set order. The display device 10 may include the fan-out line FOL disposed on the first substrate SUB1 and the display driver DIC disposed under the first substrate SUB1, so that the area of the non-display area NDA may be minimized.

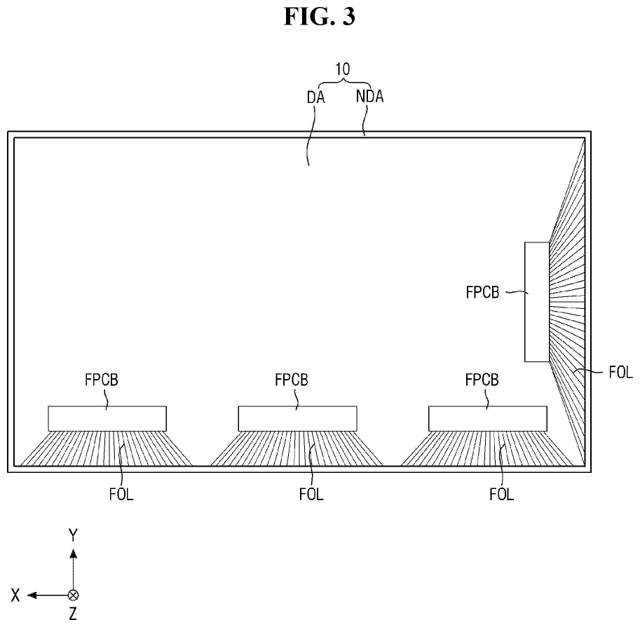

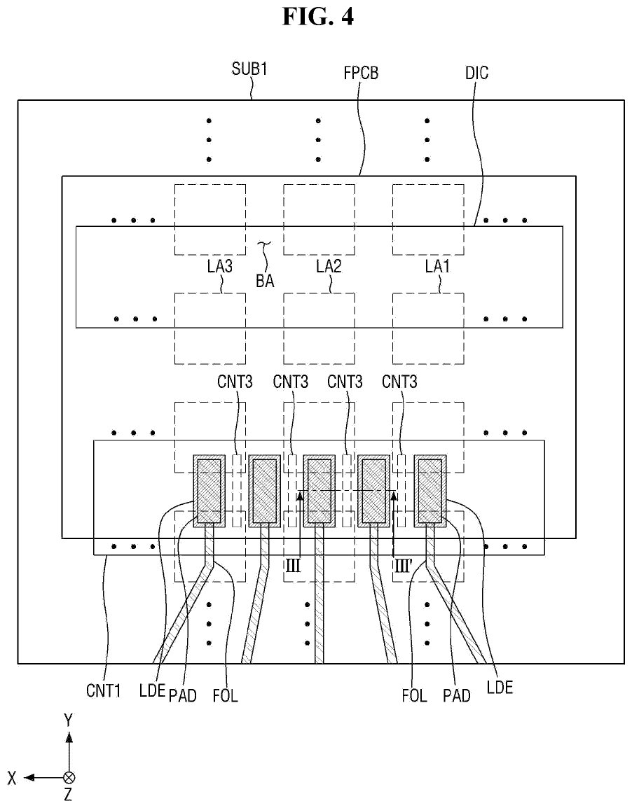

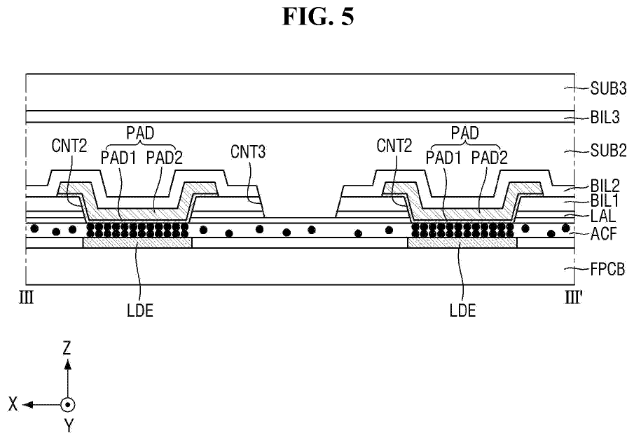

FIG. 3 is a schematic bottom view illustrating a display device according to an embodiment, FIG. 4 is a schematic enlarged bottom view illustrating a part of a display device according to an embodiment, and FIG. 5 is an example of a schematic cross-sectional view taken along line III-III′ of FIG. 4.

Referring to FIGS. 3 to 5, the flexible film FPCB, the pad portion PAD, and the fan-out line FOL may be disposed in the display area DA.

The flexible film FPCB may be disposed under the first substrate SUB1. The flexible film FPCB may be disposed on the edge of the bottom surface of the display device 10. For example, a part of the flexible film FPCB may be disposed on an edge of the long side of the display device 10, and another part of the flexible film FPCB may be disposed on an edge of the short side of the display device 10. The flexible film FPCB disposed at the edge of the long side of the display device 10 may supply the data voltage and the power voltage, and the flexible film FPCB disposed at the edge of the short side of the display device 10 may supply the gate signal, but the disclosure is not limited thereto.

The flexible film FPCB may include the lead electrode LDE. The pad portions PAD may respectively correspond to the lead electrodes LDE. The lead electrode LDE may be electrically connected to the pad portion PAD through the connection film ACF.

The pad portion PAD may be inserted into the second contact hole CNT2 of the first barrier insulating layer BIL1 and the laser absorption layer LAL, and may be exposed through the first contact hole CNT1. The pad portions PAD disposed at the edge of the long side of the display device 10 may have long sides in the second direction (Y-axis direction) and may be arranged in the first direction (X-axis direction). The pad portions PAD disposed at the edge of the short side of the display device 10 may be arranged in the second direction (Y-axis direction).

The fan-out line FOL may be integrally formed with the pad portion PAD. The fan-out line FOL may extend from the pad portion PAD to the edge of the display device 10. For example, the fan-out line FOL disposed at the edge of the long side of the display device 10 may extend in a direction opposite to the second direction (Y-axis direction) of the flexible film FPCB. The fan-out line FOL disposed at the edge of the short side of the display device 10 may extend in a direction opposite to the first direction (X-axis direction) of the flexible film FPCB. The fan-out line FOL may be electrically connected to the data line or the gate line of the display area DA through the connection portion CWL.

Referring to FIG. 5, the second barrier insulating layer BIL2, the first barrier insulating layer BILL and the laser absorption layer LAL may include a third contact hole CNT3. The third contact hole CNT3 may be etched from the top surface of the second barrier insulating layer BIL2 and penetrate to the bottom surface of the laser absorption layer LAL. The upper area of the third contact hole CNT3 may be greater than the lower area of the third contact hole CNT3. In another example, the upper area of the third contact hole CNT3 may be equal to or less than the lower area of the third contact hole CNT3. The third contact hole CNT3 may be disposed between adjacent pad portions PAD. The third contact hole CNT3 may cut the laser absorption layer LAL disposed between the adjacent pad portions PAD. Accordingly, the laser absorption layer LAL disposed between the pad portions PAD adjacent in the first direction (X-axis direction) may be separated by the third contact hole CNT3. The second substrate SUB2 may be inserted into the third contact hole CNT3, and may be exposed through the first contact hole CNT1 of the first substrate SUB1. The second substrate SUB2 may be inserted into the third contact hole CNT3 to face the connection film ACF. The separated laser absorption layers LAL may be spaced apart from each other with the second substrate SUB2 disposed therebetween. The laser absorption layer LAL or the pad portion PAD may prevent peeling between the second barrier insulating layer BIL2 and the second substrate SUB2 in the etching process of the first substrate SUB1 using ultraviolet laser. Since the second substrate SUB2 is integrally formed, the second substrate SUB2 inserted into the third contact hole CNT3 may not be peeled off during the etching process of the first substrate SUB1 using ultraviolet laser.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may be inserted into the third contact hole CNT3 to insulate adjacent pad portions PAD.

The pad portion PAD may include a lower pad portion PAD1 inserted into the second contact hole CNT2, and an upper pad portion PAD2 disposed on the lower pad portion PAD1. For example, the lower pad portion PAD1 includes titanium (Ti), and thus may be readily formed on the first substrate SUB1 before etching, but the material of the lower pad portion PAD1 is not limited thereto. The upper pad portion PAD2 includes copper (Cu), and thus may readily contact the connection portion CWL inserted into the fourth contact hole CNT4, but the material of the upper pad portion PAD2 is not limited thereto. A thickness of the upper pad portion PAD2 may be greater than the thickness of a lower pad portion PAD1. The thickness of the upper pad portion PAD2 may be greater than the thickness of the lower pad portion PAD1 by ten times or more, but the disclosure is not limited thereto.

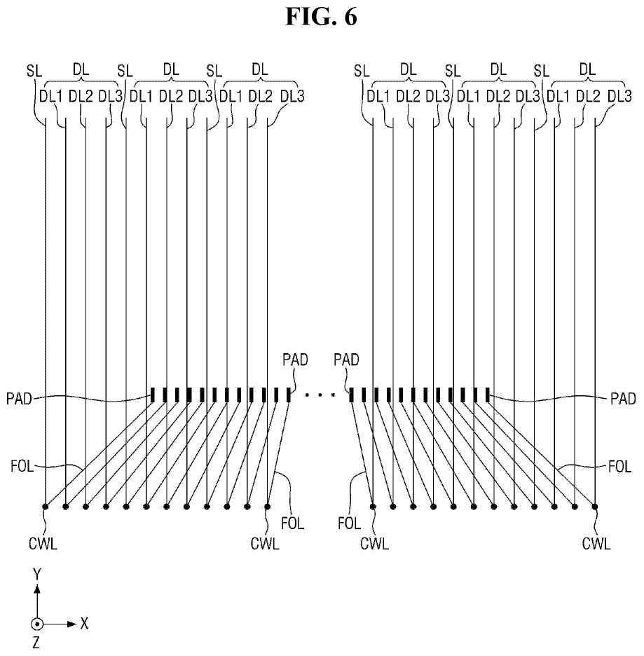

FIG. 6 is a schematic diagram illustrating a pad portion, a fan-out line, a sensing line, and a data line in a display device according to an embodiment.

Referring to FIG. 6, the display area DA may include a sensing line SL and a data line DL.

The sensing lines SL may extend in the second direction (Y-axis direction) and may be spaced apart from each other in the first direction (X-axis direction). Referring also to FIG. 2, the sensing line SL may be disposed in the second metal layer MTL2 and extend in the second direction (the Y-axis direction). The sensing line SL may be electrically connected to the fan-out line FOL of the first metal layer MTL1 through the connection portion CWL. The sensing line SL may intersect the fan-out line FOL in a plan view. The sensing line SL may receive an initialization voltage through the pad portion PAD. The sensing line SL may provide a sensing signal to the pad portion PAD.

The data lines DL may include first to third data lines DL1, DL2, and DL3. The first to third data lines DL1, DL2, and DL3 may extend in the second direction (Y-axis direction) and may be spaced apart from each other in the first direction (X-axis direction). Referring also to FIG. 2, the data line DL may be disposed in the second metal layer MTL2 and extend in the second direction (the Y-axis direction). The data line DL may be electrically connected to the fan-out line FOL of the first metal layer MTL1 through the connection portion CWL. The data line DL may intersect the fan-out line FOL in a plan view. The data line DL may receive the data voltage through the pad portion PAD.

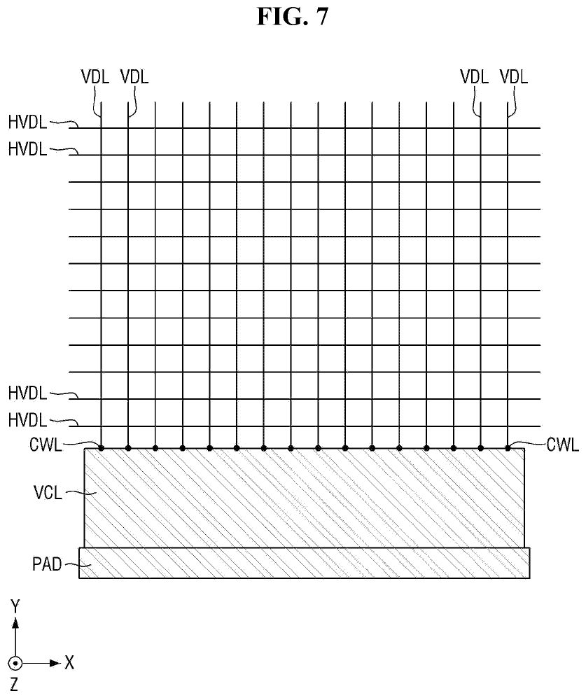

FIG. 7 is a schematic diagram illustrating a pad portion, a power connection line, a high potential line, and a horizontal voltage line in a display device according to an embodiment.

Referring to FIG. 7, the display area DA may include a high potential line VDL and a horizontal voltage line HVDL.

The high potential lines VDL may extend in the second direction (Y-axis direction) and may be spaced apart from each other in the first direction (X-axis direction). The high potential lines VDL may be connected to horizontal voltage lines HVDL intersecting them, and may supply a high potential voltage to the horizontal voltage lines HVDL. Referring also to FIG. 2, the high potential line VDL may be disposed in the second metal layer MTL2 and extend in the second direction (Y-axis direction). The high potential line VDL may be electrically connected to a power connection line VCL of the first metal layer MTL1 through the connection portion CWL. The high potential line VDL may receive a high potential voltage through the pad portion PAD.

The horizontal voltage lines HVDL may extend in the first direction (X-axis direction) and may be spaced apart from each other in the second direction (Y-axis direction). The horizontal voltage lines HVDL may be connected to the high potential lines VDL intersecting them, and may receive a high potential voltage from the high potential lines VDL. Referring also to FIG. 2, the horizontal voltage line HVDL may be disposed in the fourth metal layer MTL4 and extend in the first direction (X-axis direction).

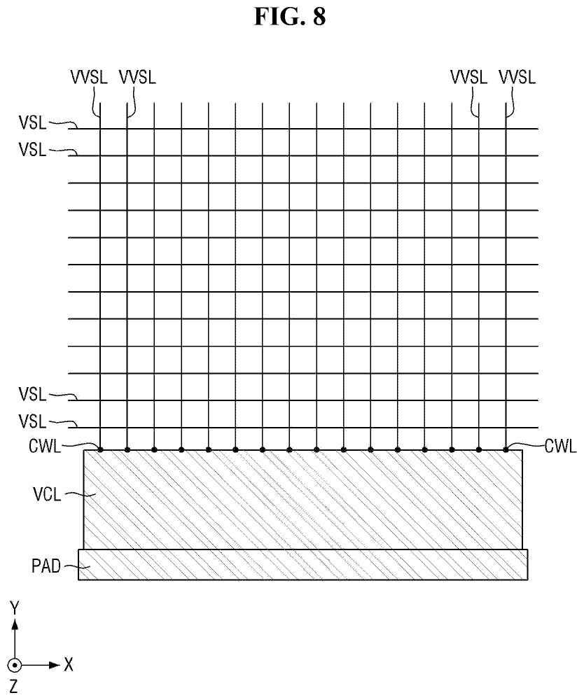

FIG. 8 is a schematic diagram illustrating a pad portion, a power connection line, a low potential line, and a vertical voltage line in a display device according to an embodiment.

Referring to FIG. 8, the display area DA may include a vertical voltage line VVSL and a low potential line VSL.

The vertical voltage lines VVSL may extend in the second direction (Y-axis direction) and may be spaced apart from each other in the first direction (X-axis direction). The vertical voltage lines VVSL may be connected to the low potential lines VSL intersecting them, and may supply a low potential voltage to the low potential lines VSL. Referring also to FIG. 2, the vertical voltage line VVSL may be disposed in the second metal layer MTL2 and extend in the second direction (Y-axis direction). The vertical voltage line VVSL may be electrically connected to the power connection line VCL of the first metal layer MTL1 through the connection portion CWL. The vertical voltage line VVSL may receive a low potential voltage through the pad portion PAD.

The low potential lines VSL may extend in the first direction (X-axis direction) and may be spaced apart from each other in the second direction (Y-axis direction). The low potential lines VSL may be connected to the vertical voltage lines VVSL intersecting them, and may receive a low potential voltage from the vertical voltage lines VVSL. Referring also to FIG. 2, the low potential line VSL may be disposed in the fourth metal layer MTL4 and extend in the first direction (X-axis direction).

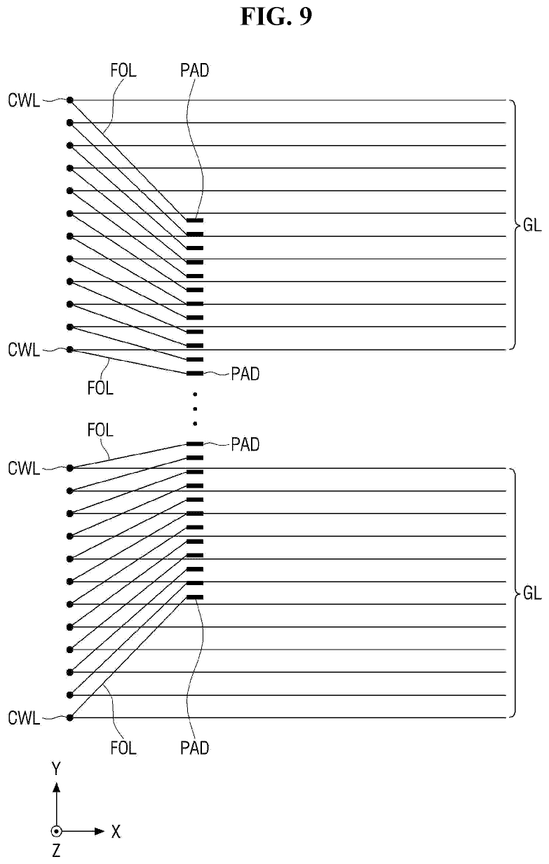

FIG. 9 is a schematic diagram illustrating a pad portion, a fan-out line, and a gate line in a display device according to an embodiment.

Referring to FIG. 9, the display area DA may include a gate line GL.

The gate lines GL may extend in the first direction (X-axis direction) and may be spaced apart from each other in the second direction (Y-axis direction). Referring also to FIG. 2, the gate line GL may be disposed in the third metal layer MTL3 or the fourth metal layer MTL4 and extend in the first direction (X-axis direction). The gate line GL may be electrically connected to the fan-out line FOL of the first metal layer MTL1 through the connection portion CWL. The gate line GL may intersect the fan-out line FOL in a plan view. The gate line GL may receive the gate signal through the pad portion PAD.

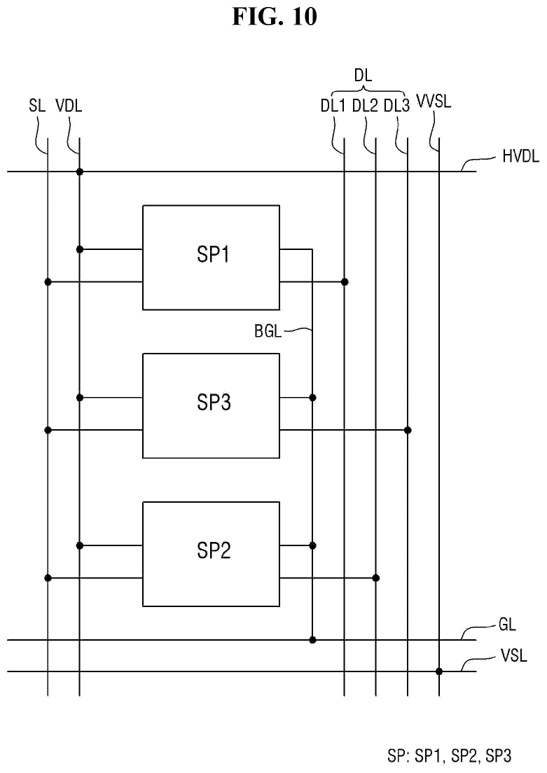

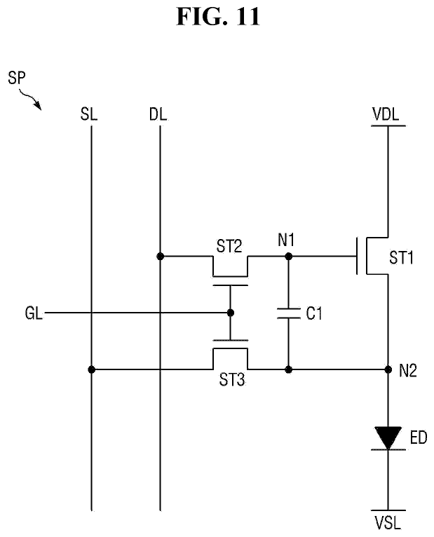

FIG. 10 is a schematic block diagram illustrating pixels and lines in a display device according to an embodiment. FIG. 11 is a schematic diagram of an equivalent circuit illustrating the pixel of FIG. 10.

Referring to FIGS. 10 and 11, the pixels SP may include first to third pixels SP1, SP2, and SP3. The pixel circuits of the first pixel SP1, the third pixel SP3 and the second pixel SP2 may be arranged in an opposite direction of the second direction (Y-axis direction), but the arrangement direction of the pixel circuits is not limited thereto.

Each of the first to third pixels SP1, SP2, and SP3 may be connected to the high potential line VDL, the sensing line SL, the gate line GL, and the data line DL.

The high potential line VDL may extend in the second direction (Y-axis direction). The high potential line VDL may be disposed on the left side of the pixel circuits of the first to third pixels SP1, SP2 and SP3. The high potential line VDL may supply a high potential voltage to a transistor of each of the first to third pixels SP1, SP2 and SP3.

The horizontal voltage line HVDL may extend in the first direction (X-axis direction). The horizontal voltage line HVDL may be disposed on the upper side of the pixel circuit of the first pixel SP1. The horizontal voltage line HVDL may be connected to the high potential line VDL. The horizontal voltage line HVDL may receive a high potential voltage from the high potential line VDL.

A sensing line SL may extend in the second direction (Y-axis direction). The sensing line SL may be disposed on the left side of the high potential line VDL. The sensing line SL may supply an initialization voltage to the pixel circuit of each of the first to third pixels SP1, SP2, and SP3. The sensing line SL may receive a sensing signal from the pixel circuit of each of the first to third pixels SP1, SP2 and SP3 to supply the sensing signal the display driver DIC.

A gate line GL may extend in the first direction (X-axis direction). Referring also to FIG. 2, the gate line GL may be disposed in the third metal layer MTL3 or the fourth metal layer MTL4. The gate line GL may be disposed on the lower side of the pixel circuit of the second pixel SP2. The gate line GL may be disposed on the upper side of the low potential line VSL. The gate line GL may supply the gate signal to an auxiliary gate line BGL.

The auxiliary gate line BGL may extend from the gate line GL in the second direction (Y-axis direction). Referring also to FIG. 2, the auxiliary gate line BGL may be disposed in the third metal layer MTL3. A part of the auxiliary gate line BGL may be the gate electrode GE of a second transistor ST2, and another part of the auxiliary gate line BGL may be the gate electrode GE of a third transistor ST3. The auxiliary gate line BGL may be disposed on a right side of the pixel circuits of the first to third pixels SP1, SP2 and SP3. The auxiliary gate line BGL may supply the gate signals received from the gate line GL to the pixel circuits of the first to third pixels SP1, SP2 and SP3.

The data line DL may extend in the second direction (Y-axis direction). The data line DL may supply a data voltage to the pixel SP. The data lines DL may include first to third data lines DL1, DL2, and DL3.

The first data line DL1 may extend in the second direction (Y-axis direction). The first data line DL1 may be disposed on the right side of the auxiliary gate line BGL. The first data line DL1 may supply the data voltage received from the display driver DIC to the pixel circuit of the first pixel SP1.

The second data line DL2 may extend in the second direction (Y-axis direction). The second data line DL2 may be disposed on the right side of the first data line DL1. The second data line DL2 may supply the data voltage received from the display driver DIC to the pixel circuit of the second pixel SP2.

The third data line DL3 may extend in the second direction (Y-axis direction). The third data line DL3 may be disposed on the right side of the second data line DL2. The third data line DL3 may supply the data voltage received from the display driver DIC to the pixel circuit of the third pixel SP3.

The vertical voltage line VVSL may extend in the second direction (Y-axis direction). The vertical voltage line VVSL may be disposed on the right side of the third data line DL3. The vertical voltage line VVSL may be connected to the low potential line VSL and may supply a low potential voltage to the low potential line VSL.

The low potential line VSL may extend in the first direction (X-axis direction). The low potential line VSL may be disposed on the lower side of the gate line GL. The low potential line VSL may supply the low potential voltage received from the vertical voltage line VVSL to the light emitting element ED of the first to third pixels SP1, SP2, and SP3.

Each of the first to third pixels SP1, SP2, and SP3 may include a pixel circuit and the light emitting element ED. The pixel circuit of each of the first to third pixels SP1, SP2, and SP3 may include first to third transistors ST1, ST2, and ST3 and a first capacitor C1.

The first transistor ST1 may include a gate electrode, a drain electrode, and a source electrode. The gate electrode of the first transistor ST1 may be connected to a first node N1, the drain electrode thereof may be connected to the high potential line VDL, and the source electrode thereof may be connected to a second node N2. The first transistor ST1 may control a drain-source current (or driving current) based on a data voltage applied to the gate electrode.

The light emitting element ED may include at least one light emitting element ED. In case that the light emitting element ED includes the light emitting elements ED, the light emitting elements ED may be connected in series or in parallel. The light emitting element ED may receive a driving current from the first transistor ST1 to emit light. The light emission amount or the luminance of the light emitting element ED may be proportional to the magnitude of the driving current. The light emitting element ED may be an inorganic light emitting element including an inorganic semiconductor, but is not limited thereto.

The first electrode of the light emitting element ED may be connected to the second node N2, and the second electrode of the light emitting element ED may be connected to the low potential line VSL. The first electrode of the light emitting element ED may be connected to the source electrode of the first transistor ST1, the drain electrode of the third transistor ST3, and the second capacitor electrode of the first capacitor C1, through the second node N2.

The second transistor ST2 may be turned on by the gate signal of the gate line GL to electrically connect the data line DL to the first node N1 which is the gate electrode of the first transistor ST1. The second transistor ST2 may be turned on according to the gate signal to supply the data voltage to the first node N1. The gate electrode of the second transistor ST2 may be connected to the gate line GL, the drain electrode thereof may be connected to the data line DL, and the source electrode thereof may be connected to the first node N1.

The third transistor ST3 may be turned on by the gate signal of the gate line GL to electrically connect the sensing line SL to the second node N2 which is the source electrode of the first transistor ST1. When the third transistor ST3 is turned on in response on the gate signal, the initialization voltage may be supplied to the second node N2 and the sensing signal may be supplied to the sensing line SL. The gate electrode of the third transistor ST3 may be connected to the gate line GL, the drain electrode thereof may be connected to the second node N2, and the source electrode thereof may be connected to the sensing line SL.

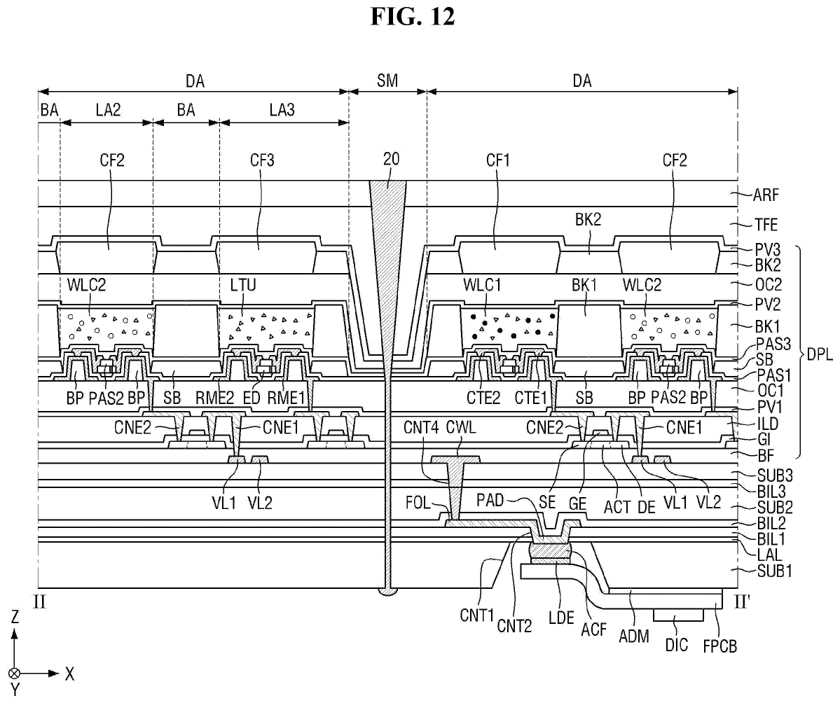

FIG. 12 is a schematic cross-sectional view taken along line II-IT of FIG. 1.

Referring to FIG. 12, the tiled display device TD may include the display devices 10 and a bonding member 20. The tiled display device TD may include first to fourth display devices 10-1 to 10-4. The number and connection relationship of the display devices 10 are not limited to the embodiment of FIG. 1. The number of the display devices 10 may be determined according to the size of each of the display devices 10 and the tiled display device TD.

The display device 10 may include a display area DA and a non-display area NDA. The display area DA may include pixels SP to display an image. The non-display area NDA may be disposed around the display area DA to surround the display area DA, and may not display an image.

The tiled display device TD may include a coupling area SM disposed between display areas DA. The tiled display device TD may be formed by connecting non-display areas NDA of the adjacent display devices 10. The display devices 10 may be connected to each other through the bonding member 20 or an adhesive member disposed in the coupling area SM. The coupling area SM of each of the display devices 10 may not include a pad member or a fan-out line connected to the pad member. Accordingly, the distance between the display areas DA of the display devices 10 may be small enough that the coupling area SM is not recognized by the user. Further, the reflectance of external light of the display areas DA of the display devices 10 may be substantially the same as that of the coupling area SM. Accordingly, in the tiled display device TD, the coupling area SM disposed between the display devices 10 may be prevented from being recognized by the user, thereby reducing a sense of disconnection between the display devices 10 and improving a sense of immersion in an image.

The tiled display device TD may bond the side surfaces of the adjacent display devices 10 to each other by using the bonding member 20 disposed between the display devices 10. The bonding member 20 may connect the side surfaces of the first to fourth display devices 10-1 to 10-4 arranged in a grid form to implement the tiled display device TD. The bonding member 20 may bond the side surfaces of the adjacent display devices 10 to each other, specifically, the side surfaces of the first substrates SUB1, the side surfaces of the laser absorption layers LAL, the side surfaces of the first and second barrier insulating layers BIL1 and BIL2, the side surfaces of the second substrates SUB2, the side surfaces of the third barrier insulating layers BIL3, the side surfaces of the third substrate SUB3, the side surfaces of the display layers DPL, the side surfaces of the encapsulation layers TFE, and the side surfaces of the anti-reflection films ARF.

For example, the bonding member 20 may be made of an adhesive or a double-sided tape having a relatively thin thickness to minimize the gap formed between the display devices 10. For another example, the bonding member 20 may be formed of a bonding frame having a relatively thin thickness to minimize the gap formed between the display devices 10. Accordingly, in the tiled display device TD, it is possible to prevent the user from recognizing the coupling area SM disposed between the display devices 10.

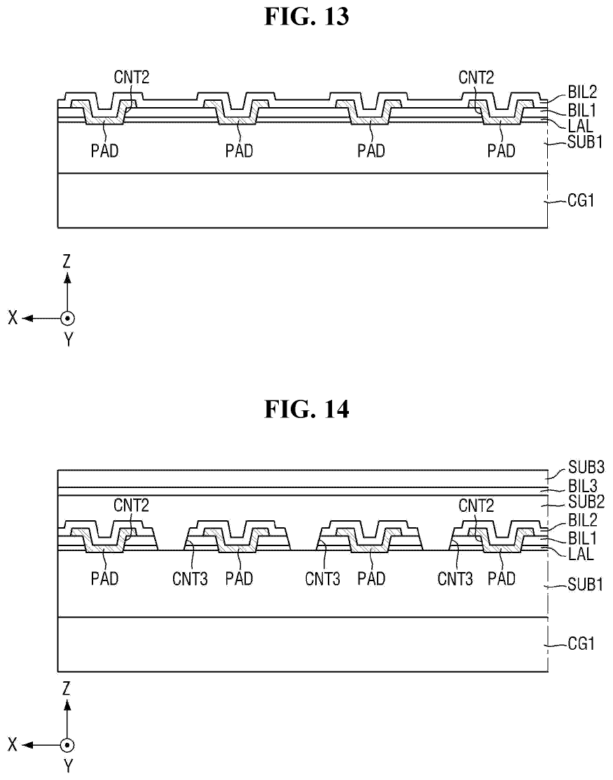

FIGS. 13 to 19 are schematic cross-sectional views illustrating a manufacturing process of a display device according to an embodiment.

In FIG. 13, a first carrier substrate CG1 may support the display device 10 in the manufacturing process of the display device 10. For example, the first carrier substrate CG1 may be a carrier glass, but is not limited thereto.

The first substrate SUB1 may be disposed on the first carrier substrate CG1. The first substrate SUB1 may be a base substrate or a base member. For example, the first substrate SUB1 may include an insulating material, for example, a polymer resin such as polyimide (PI), but the disclosure is not limited thereto.

The laser absorption layer LAL may be disposed on the first substrate SUB1. The laser absorption layer LAL may absorb ultraviolet laser to prevent transmission of the ultraviolet laser. Here, the ultraviolet laser may have a wavelength of about 300 nm to about 400 nm, preferably, a wavelength of about 340 nm to about 350 nm. For example, the laser absorption layer LAL may include amorphous silicon (a-Si). The thickness of the laser absorption layer LAL may be in a range of about 300 Å to about 1000 Å, preferably, about 500 Å or more in order to effectively block the ultraviolet laser.

The first barrier insulating layer BIL1 may be disposed on the laser absorption layer LAL. The first barrier insulating layer BIL1 may include an inorganic layer capable of preventing permeation of air or moisture.

The first barrier insulating layer BIL1 and the laser absorption layer LAL may include the second contact hole CNT2. The second contact hole CNT2 may be etched from the top surface of the first barrier insulating layer BIL1 and penetrate to the bottom surface of the laser absorption layer LAL. For example, the upper width of the second contact hole CNT2 may be greater than the lower width of the second contact hole CNT2.

The pad portion PAD may be integrally formed with the fan-out line FOL and inserted into the second contact hole CNT2. The pad portion PAD may be formed of a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The second barrier insulating layer BIL2 may be disposed on the pad portion PAD and the first barrier insulating layer BILL The second barrier insulating layer BIL2 may include an inorganic layer capable of preventing permeation of air or moisture.

In FIG. 14, the second barrier insulating layer BIL2, the first barrier insulating layer BILL and the laser absorption layer LAL may include the third contact hole CNT3. The third contact hole CNT3 may be etched from the top surface of the second barrier insulating layer BIL2 and penetrate to the bottom surface of the laser absorption layer LAL. The third contact hole CNT3 may be disposed between adjacent pad portions PAD. The third contact hole CNT3 may cut the laser absorption layer LAL disposed between the adjacent pad portions PAD. Therefore, the laser absorption layer LAL disposed between the pad portions PAD adjacent in the first direction (X-axis direction) may be separated by the third contact hole CNT3.

The second substrate SUB2 may be disposed on the second barrier insulating layer BIL2. For example, the second substrate SUB2 may include an insulating material, for example, a polymer resin such as polyimide (PI), but the disclosure is not limited thereto. The second substrate SUB2 may be inserted into the third contact hole CNT3. The bottom surface of the second substrate SUB2 inserted into the third contact hole CNT3 may contact the top surface of the first substrate SUB1. The separated laser absorption layers LAL may be spaced apart from each other with the second substrate SUB2 disposed therebetween.

The third barrier insulating layer BIL3 may be disposed on the second substrate SUB2. The third barrier insulating layer BIL3 may include an inorganic layer capable of preventing permeation of air or moisture.

The third substrate SUB3 may be disposed on the third barrier insulating layer BIL3. For example, the third substrate SUB3 may include an insulating material, for example, a polymer resin such as polyimide (PI), but the disclosure is not limited thereto. As another example, the third substrate SUB3 may be omitted.

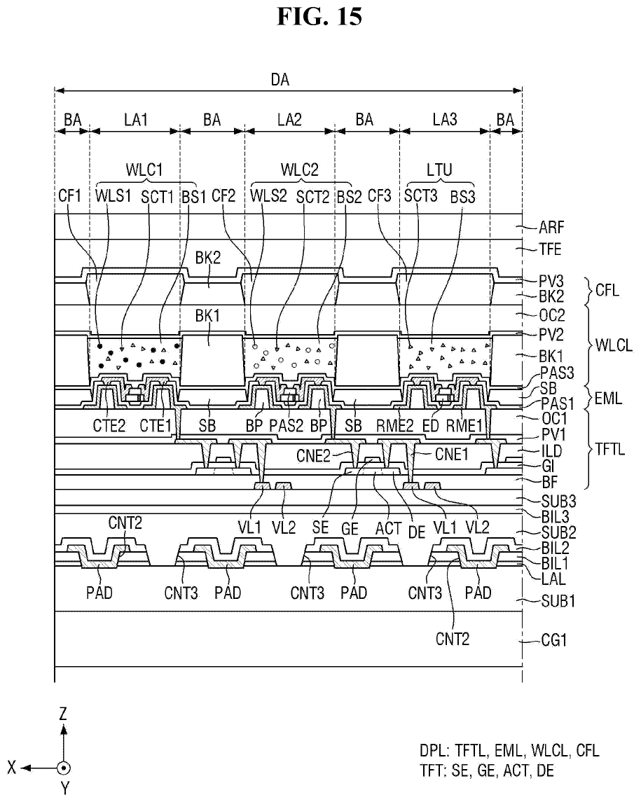

In FIG. 15, the display layer DPL may be stacked on the third substrate SUB3. The thin film transistor layer TFTL, the light emitting element layer EML, the wavelength conversion layer WLCL, and the color filter layer CFL may be sequentially stacked on the third substrate SUB3. The encapsulation layer TFE may cover the top and side surfaces of the display layer DPL. The anti-reflection film ARF may be formed on the encapsulation layer TFE.

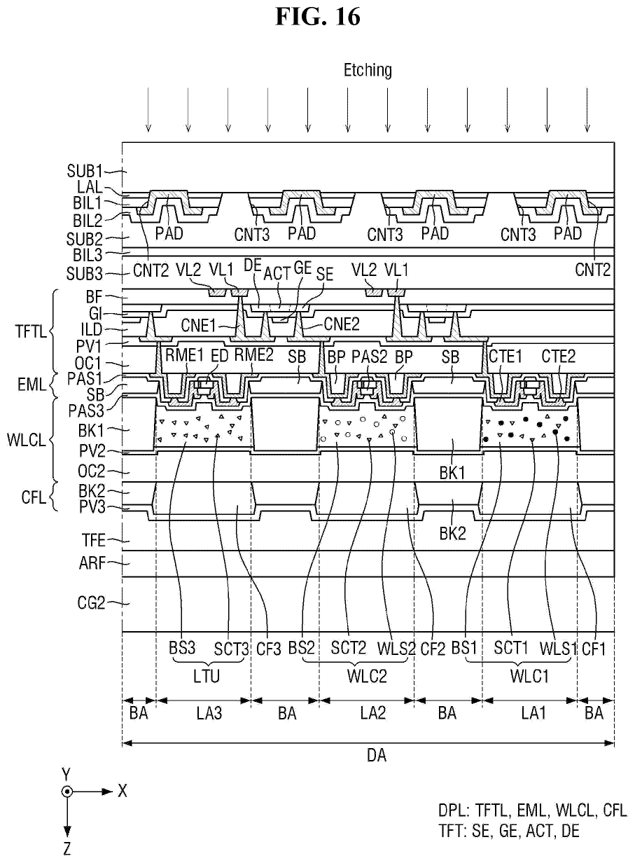

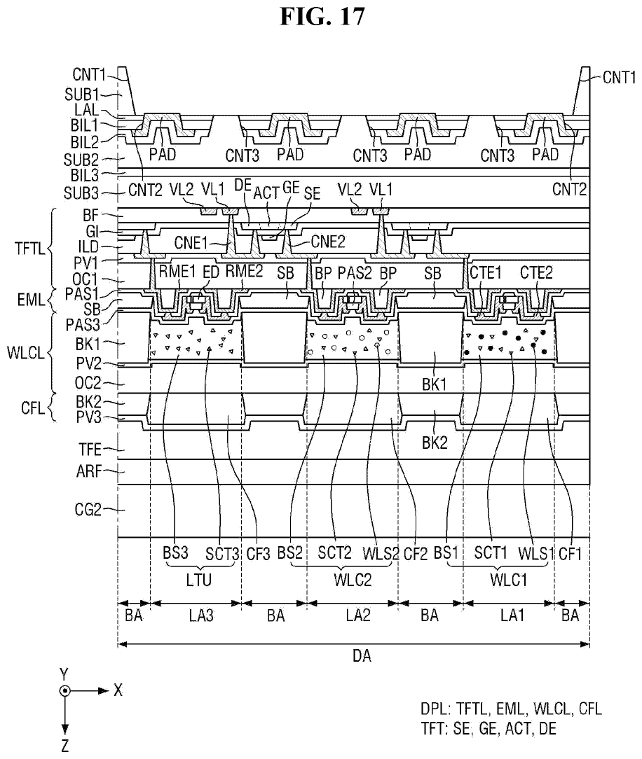

In FIGS. 16 and 17, the display device 10 being manufactured may be vertically inverted to attach the flexible film FPCB. The first carrier substrate CG1 may be removed from the first substrate SUB1. For example, the first carrier substrate CG1 may be removed from the bottom surface of the first substrate SUB1 using a sacrificial layer (not shown) disposed between the first carrier substrate CG1 and the first substrate SUB1, but the disclosure is not limited thereto.

A second carrier substrate CG2 may be disposed on a surface of the anti-reflection film ARF. The second carrier substrate CG2 may support the vertically inverted display device 10. For example, the second carrier substrate CG2 may be a carrier glass, but is not limited thereto.

A surface of the first substrate SUB1 may be subjected to at least one of a dry etching process, a plasma etching process, or a laser etching process. For example, a surface of the first substrate SUB1 may be patterned through a laser etching process. The laser absorption layer LAL may absorb an ultraviolet laser in the etching process of the first substrate SUB1 to prevent transmission of the ultraviolet laser. Here, the ultraviolet laser may have a wavelength of about 300 nm to about 400 nm, preferably, a wavelength of about 340 nm to about 350 nm. The laser absorption layer LAL or the pad portion PAD may prevent peeling between the second barrier insulating layer BIL2 and the second substrate SUB2 during the etching process of the first substrate SUB1 using ultraviolet laser. Since the second substrate SUB2 is integrally formed, the second substrate SUB2 inserted into the third contact hole CNT3 may not be peeled off during the etching process of the first substrate SUB1 using ultraviolet laser. Accordingly, the first contact hole CNT1 may be provided in the first substrate SUB1, and may expose the pad portions PAD, the laser absorption layer LAL, and the second substrate SUB2. A surface of the pad portion PAD may protrude from the laser absorption layer LAL, but the disclosure is not limited thereto.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may be inserted into the third contact hole CNT3 to insulate adjacent pad portions PAD.

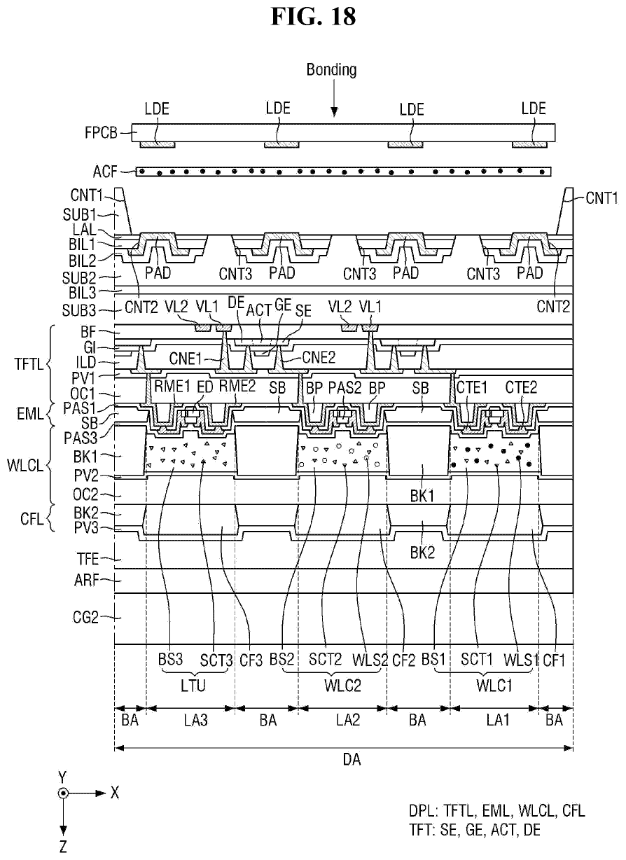

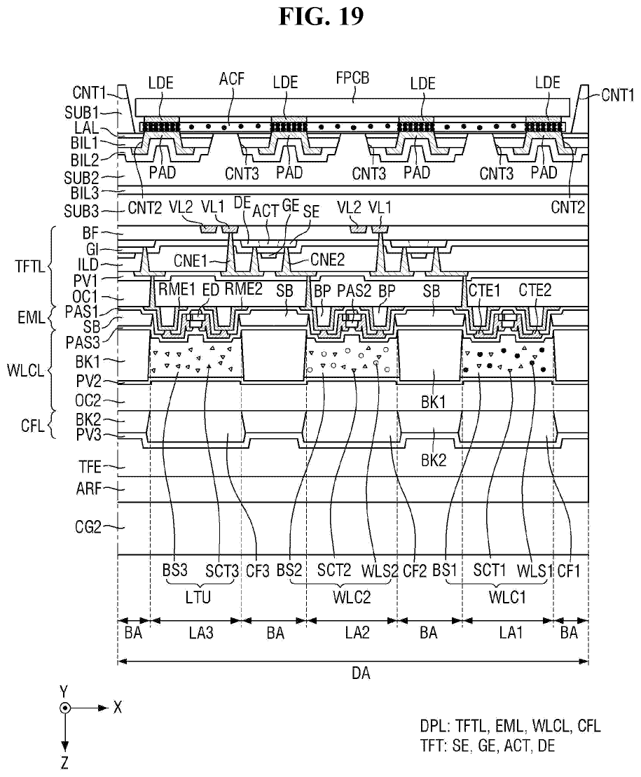

In FIGS. 18 and 19, the flexible film FPCB may be disposed on a surface of the first substrate SUB1. The flexible film FPCB and the lead electrode LDE may be aligned on the pad portion PAD through an alignment process. For example, the lead electrode LDE of the flexible film FPCB may be attached to the pad portion PAD through ultrasonic bonding or thermocompression bonding, but the bonding method is not limited thereto. The connection film ACF may have conductivity in a region where the pad portion PAD and the lead electrode LDE contact each other, and may electrically connect the flexible film FPCB to the pad portion PAD.

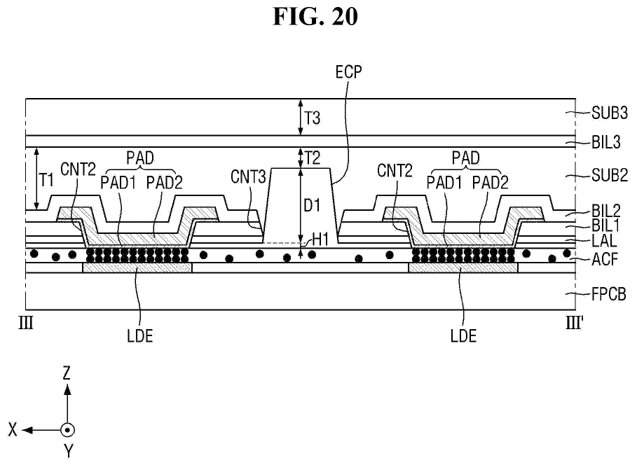

FIG. 20 is another example of a schematic cross-sectional view taken along line III-III′ of FIG. 4. The display device of FIG. 20 has a configuration in which an etched portion ECP is included in the display device of FIG. 5, so that the same configurations as the above-described configurations will be briefly described, or a description thereof will be omitted.

Referring to FIG. 20, the second barrier insulating layer BIL2, the first barrier insulating layer BILL and the laser absorption layer LAL may include the third contact hole CNT3. The third contact hole CNT3 may be etched from the top surface of the second barrier insulating layer BIL2 and penetrate to the bottom surface of the laser absorption layer LAL. The upper area of the third contact hole CNT3 may be greater than the lower area of the third contact hole CNT3. The third contact hole CNT3 may be disposed between adjacent pad portions PAD. The third contact hole CNT3 may cut the laser absorption layer LAL disposed between the adjacent pad portions PAD.

The second substrate SUB2 may be inserted into the third contact hole CNT3, and may be exposed through the first contact hole CNT1 of the first substrate SUB1. The second substrate SUB2 may include the etched portion ECP. The etched portion ECP may be formed by etching the second substrate SUB2 inserted into the third contact hole CNT3. The etched portion ECP may be recessed from the surface of the laser absorption layer LAL. For example, in the process of forming the etched portion ECP using ultraviolet laser, the etching rate of the second substrate SUB2 may be significantly faster than the etching rate of the laser absorption layer LAL or the pad portion PAD. The depth of the etched portion ECP may increase as the intensity of the ultraviolet laser increases, and may increase as the number of scans of the ultraviolet laser increases. The second substrate SUB2 and the connection film ACF may be spaced apart from each other by a depth D1 of the etched portion ECP and a protrusion height H1 of the pad portion PAD. The depth D1 of the etched portion ECP may be greater than the sum of the thicknesses of the laser absorption layer LAL, the first and second barrier insulating layers BIL1 and BIL2, and the pad portion PAD, but the disclosure is not limited thereto. The depth D1 of the etched portion ECP may be greater than the protrusion height H1 of the pad portion PAD by ten times or more, but the disclosure is not limited thereto. The etched portion ECP may face the connection film ACF.

Accordingly, the laser absorption layer LAL disposed between the pad portions PAD adjacent in the first direction (X-axis direction) may be separated by the etched portion ECP and the third contact hole CNT3. The separated laser absorption layers LAL may be spaced apart from each other with the etched portion ECP disposed therebetween. The laser absorption layer LAL or the pad portion PAD may prevent peeling between the second barrier insulating layer BIL2 and the second substrate SUB2 in the etching process of the first substrate SUB1 using ultraviolet laser. Since the second substrate SUB2 is integrally formed, the second substrate SUB2 including the etched portion ECP may not be peeled off during the etching process using ultraviolet laser. Since the second substrate SUB2 includes the etched portion ECP, a compression pressure or a bonding pressure may be concentrated on the protruding pad portion PAD during the bonding process of the pad portion PAD and the lead electrode LDE, and the conductivity of the connection film ACF may be improved.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may include the etched portion ECP to insulate adjacent pad portions PAD.

A first thickness T1 of the second substrate SUB2 may be greater than a second thickness T2 of the second substrate SUB2 due to the etched portion ECP. The first thickness T1 of the second substrate SUB2 may be the thickness of a portion of the second substrate SUB2 that does not overlap the pad portion PAD and the third contact hole CNT3. The first thickness T1 of the second substrate SUB2 may be greater than a third thickness T3 of the third substrate SUB3. In case that the depth D1 of the etched portion ECP is maximum, the second thickness T2 of the second substrate SUB2 due to the etched portion ECP may be smaller than the third thickness T3 of the third substrate SUB3. In case that the depth D1 of the etched portion ECP is minimum, the second thickness T2 of the second substrate SUB2 due to the etched portion ECP may be greater than the third thickness T3 of the third substrate SUB3. Here, the depth D1 of the etched portion ECP may have a depth (e.g., a predetermined or selectable depth) that allows improvement of the conductivity of the connection film ACF during the bonding process of the pad portion PAD and the lead electrode LDE.

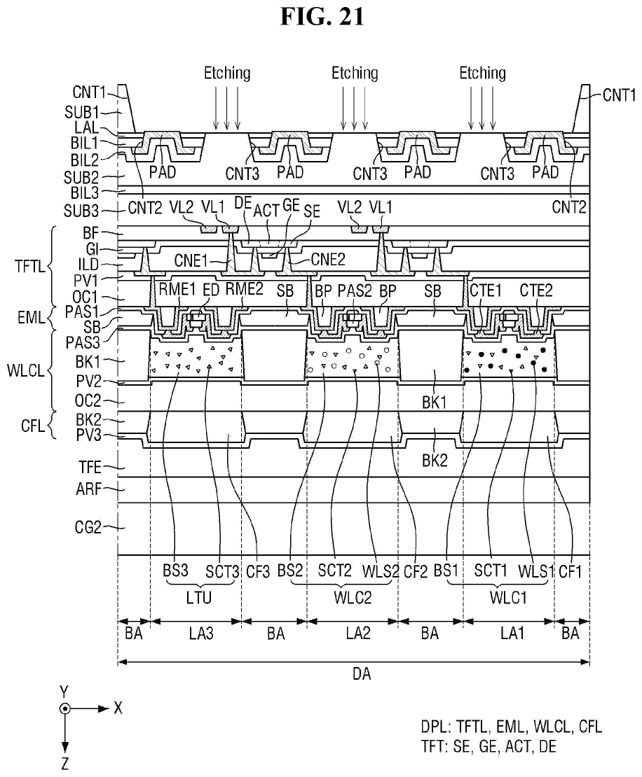

FIGS. 21 to 24 are schematic cross-sectional views illustrating a manufacturing process of a display device according to another embodiment. Here, FIG. 21 may show a manufacturing process after the manufacturing process of FIG. 17.

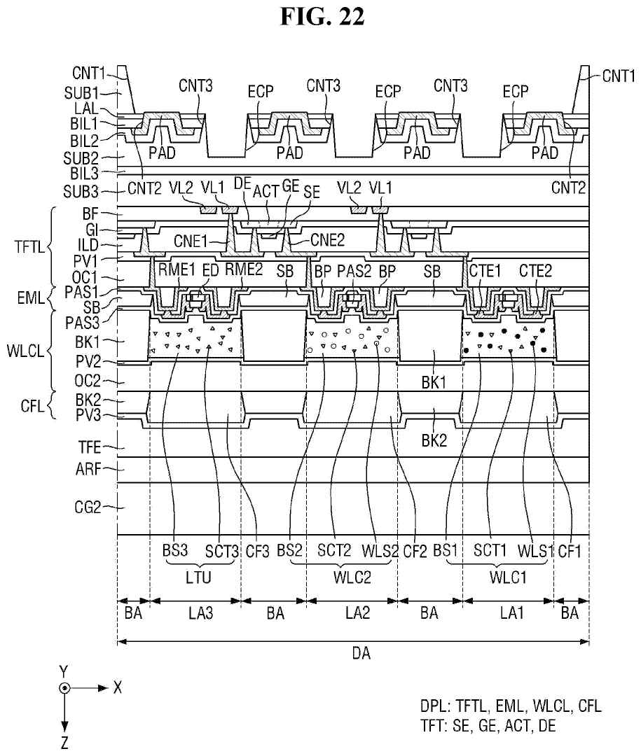

In FIGS. 21 and 22, a surface of the second substrate SUB2 exposed through the first contact hole CNT1 may be subjected to at least one of a dry etching process, a plasma etching process, or a laser etching process. For example, a surface of the second substrate SUB2 may be patterned through a laser etching process. The laser absorption layer LAL may absorb an ultraviolet laser in the etching process of the second substrate SUB2 to prevent transmission of the ultraviolet laser. Here, the ultraviolet laser may have a wavelength of about 300 nm to about 400 nm, preferably, a wavelength of about 340 nm to about 350 nm.

A part of the second substrate SUB2 may be etched to form the etched portion ECP. The laser absorption layer LAL disposed between the pad portions PAD adjacent in the first direction (X-axis direction) may be separated by the etched portion ECP and the third contact hole CNT3. The separated laser absorption layers LAL may be spaced apart from each other with the etched portion ECP disposed therebetween. The laser absorption layer LAL or the pad portion PAD may prevent peeling between the second barrier insulating layer BIL2 and the second substrate SUB2 in the etching process using ultraviolet laser. Since the second substrate SUB2 is integrally formed, the second substrate SUB2 including the etched portion ECP may not be peeled off during the etching process using ultraviolet laser.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may include the etched portion ECP to insulate adjacent pad portions PAD.

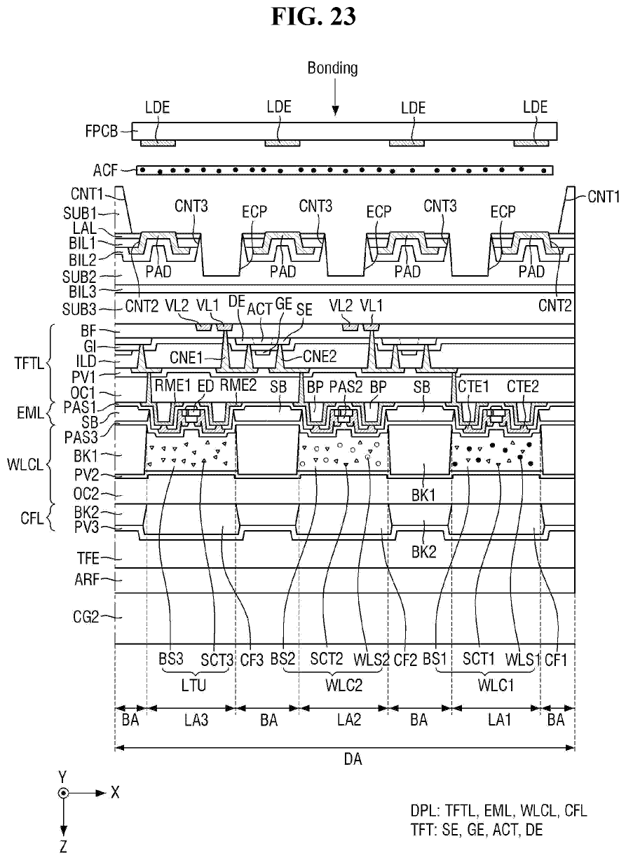

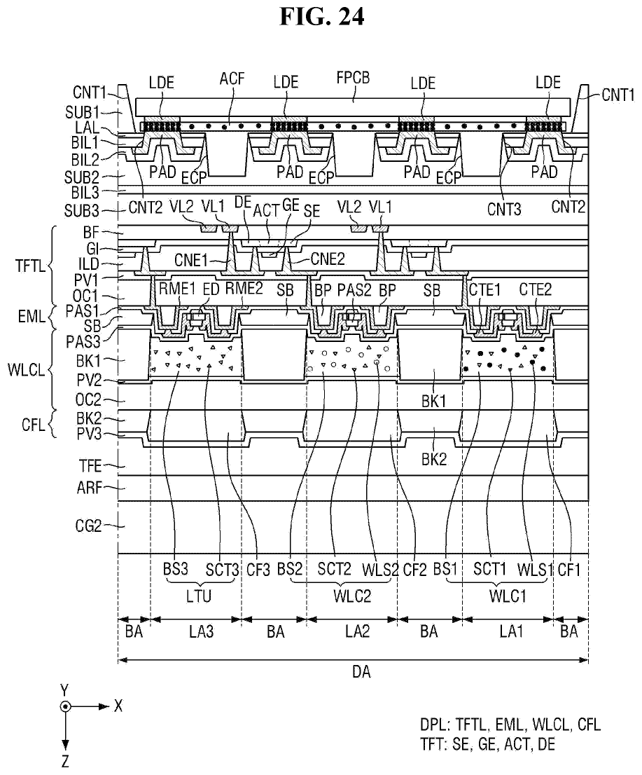

In FIGS. 23 and 24, the flexible film FPCB may be disposed on a surface of the first substrate SUB1. The flexible film FPCB and the lead electrode LDE may be aligned on the pad portion PAD through an alignment process. For example, the lead electrode LDE of the flexible film FPCB may be attached to the pad portion PAD through ultrasonic bonding or thermocompression bonding, but the bonding method is not limited thereto. The connection film ACF may have conductivity in a region where the pad portion PAD and the lead electrode LDE contact each other, and may electrically connect the flexible film FPCB to the pad portion PAD.

Since the second substrate SUB2 includes the etched portion ECP, a compression pressure or a bonding pressure may be concentrated on the protruding pad portion PAD during the bonding process of the pad portion PAD and the lead electrode LDE, and the conductivity of the connection film ACF may be improved.

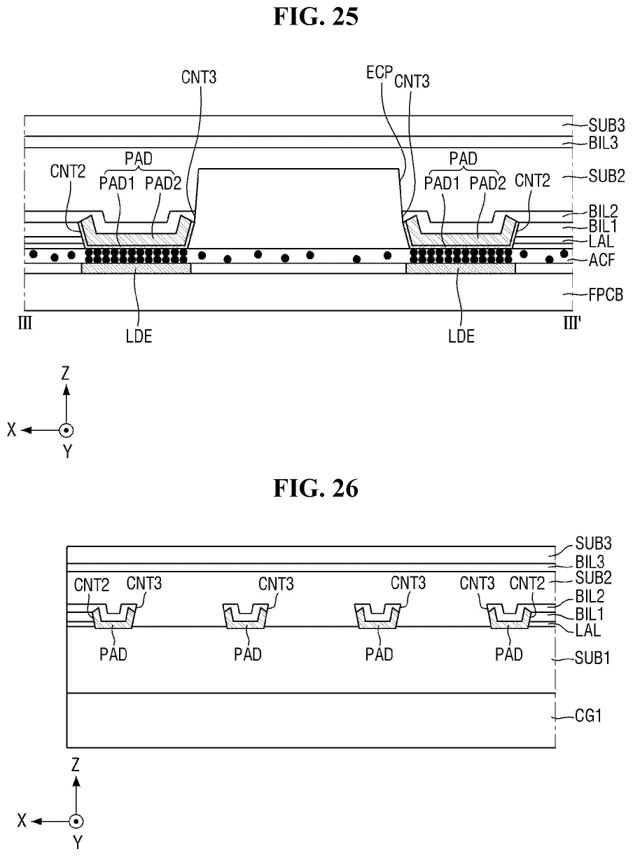

FIG. 25 is another example of a schematic cross-sectional view taken along line III-III′ of FIG. 4. The display device illustrated in FIG. 25 is different from the display device illustrated in FIG. 20 in the configuration of the third contact hole CNT3. A description of the same configuration as the above-described configuration will be briefly given or omitted.

Referring to FIG. 25, the second barrier insulating layer BIL2, the first barrier insulating layer BILL and the laser absorption layer LAL may include the third contact hole CNT3. The third contact hole CNT3 may be etched from the top surface of the second barrier insulating layer BIL2 and penetrate to the bottom surface of the laser absorption layer LAL. The lower area of the third contact hole CNT3 may be greater than the upper area of the third contact hole CNT3. The third contact hole CNT3 may have an undercut structure. The third contact hole CNT3 may be disposed between adjacent pad portions PAD. The third contact hole CNT3 may remove the laser absorption layer LAL and the first and second barrier insulating layers BIL1 and BIL2 disposed between the adjacent pad portions PAD, and the side surfaces of the pad portions PAD may be exposed through the third contact hole CNT3.

The second substrate SUB2 may be exposed through the third contact hole CNT3 and the first contact hole CNT1 of the first substrate SUB1. The second substrate SUB2 may include the etched portion ECP. The etched portion ECP may be formed by etching the second substrate SUB2 inserted into the third contact hole CNT3. The etched portion ECP may be recessed from the surface of the laser absorption layer LAL. For example, in the process of forming the etched portion ECP using ultraviolet laser, an etching rate of the second substrate SUB2 may be significantly faster than an etching rate of the laser absorption layer LAL or the pad portion PAD. The depth of the etched portion ECP may increase as the intensity of the ultraviolet laser increases, and may increase as the number of scans of the ultraviolet laser increases.

Accordingly, the pad portions PAD adjacent in the first direction (X-axis direction) may be separated by the third contact hole CNT3. The adjacent pad portions PAD may be spaced apart from each other with the etched portion ECP disposed therebetween. The laser absorption layer LAL may not exist between the adjacent pad portions PAD. Since the second substrate SUB2 is integrally formed, the second substrate SUB2 including the etched portion ECP may not be peeled off during the etching process using ultraviolet laser. The second substrate SUB2 includes the etched portion ECP, and the laser absorption layer LAL and the first and second barrier insulating layers BIL1 and BIL2 that are disposed between the adjacent pad portions PAD are removed to expose the side surfaces of the pad portions PAD, so that a compression pressure or a bonding pressure may be concentrated on the protruding pad portion PAD during the bonding process of the pad portion PAD and the lead electrode LDE, and the conductivity of the connection film ACF may be improved.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may include the etched portion ECP to insulate adjacent pad portions PAD.

FIGS. 26 to 32 are schematic cross-sectional views illustrating a manufacturing process of a display device according to another embodiment.

In FIG. 26, a first carrier substrate CG1 may support the display device 10 in the manufacturing process of the display device 10. For example, the first carrier substrate CG1 may be a carrier glass, but is not limited thereto.

The first substrate SUB1 may be disposed on the first carrier substrate CG1. For example, the first substrate SUB1 may include an insulating material, for example, a polymer resin such as polyimide (PI), but the disclosure is not limited thereto.

The laser absorption layer LAL may be disposed on the first substrate SUB1. The laser absorption layer LAL may absorb an ultraviolet laser to prevent transmission of the ultraviolet laser.

The first barrier insulating layer BIL1 may be disposed on the laser absorption layer LAL. The first barrier insulating layer BIL1 may include an inorganic layer capable of preventing permeation of air or moisture.

The first barrier insulating layer BIL1 and the laser absorption layer LAL may include the second contact hole CNT2. The second contact hole CNT2 may be etched from the top surface of the first barrier insulating layer BIL1 and penetrate to the bottom surface of the laser absorption layer LAL. For example, the upper width of the second contact hole CNT2 may be greater than the lower width of the second contact hole CNT2.

The pad portion PAD may be integrally formed with the fan-out line FOL and inserted into the second contact hole CNT2. The pad portion PAD may be formed of a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), copper (Cu), and the like.

The second barrier insulating layer BIL2 may be disposed on the pad portion PAD and the first barrier insulating layer BILL The second barrier insulating layer BIL2 may include an inorganic layer capable of preventing permeation of air or moisture.

The second barrier insulating layer BIL2, the first barrier insulating layer BILL and the laser absorption layer LAL may include the third contact hole CNT3. The third contact hole CNT3 may be etched from the top surface of the second barrier insulating layer BIL2 and penetrate to the bottom surface of the laser absorption layer LAL. The lower area of the third contact hole CNT3 may be greater than the upper area of the third contact hole CNT3. The third contact hole CNT3 may have an undercut structure. The third contact hole CNT3 may be disposed between adjacent pad portions PAD. The third contact hole CNT3 may remove the laser absorption layer LAL and the first and second barrier insulating layers BIL1 and BIL2 disposed between the adjacent pad portions PAD. Accordingly, the pad portions PAD adjacent in the first direction (X-axis direction) may face each other through the third contact hole CNT3.

The second substrate SUB2 may be disposed on the second barrier insulating layer BIL2. For example, the second substrate SUB2 may include an insulating material such as a polymer resin such as polyimide (PI), but the disclosure is not limited thereto. The second substrate SUB2 may be inserted into the third contact hole CNT3. The bottom surface of the second substrate SUB2 inserted into the third contact hole CNT3 may contact the top surface of the first substrate SUB1. The adjacent pad portions PAD may be spaced apart from each other with the second substrate SUB2 disposed therebetween.

The third barrier insulating layer BIL3 may be disposed on the second substrate SUB2. The third barrier insulating layer BIL3 may include an inorganic layer capable of preventing permeation of air or moisture.

The third substrate SUB3 may be disposed on the third barrier insulating layer BIL3. For example, the third substrate SUB3 may include an insulating material, for example, a polymer resin such as polyimide (PI), but the disclosure is not limited thereto. As another example, the third substrate SUB3 may be omitted.

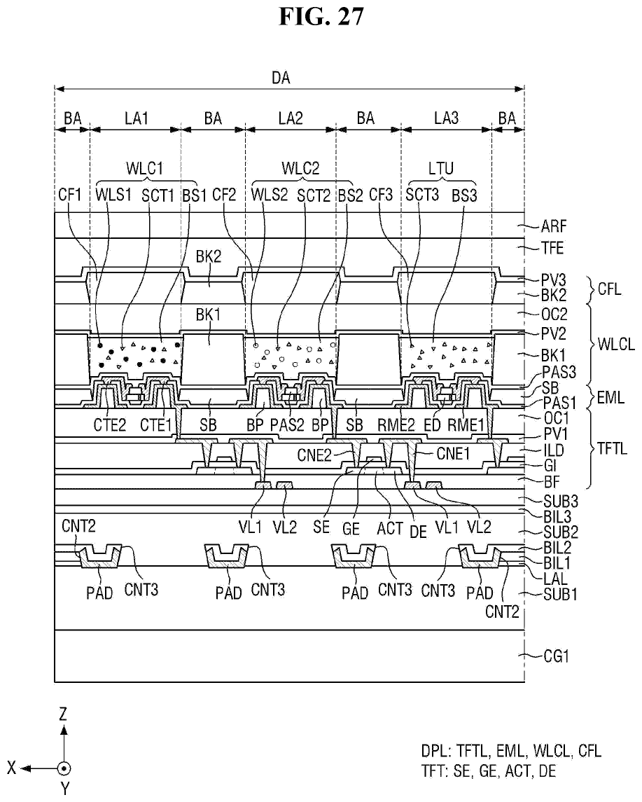

In FIG. 27, the display layer DPL may be stacked on the third substrate SUB3. The thin film transistor layer TFTL, the light emitting element layer EML, the wavelength conversion layer WLCL, and the color filter layer CFL may be sequentially stacked on the third substrate SUB3. The encapsulation layer TFE may cover the top and side surfaces of the display layer DPL. The anti-reflection film ARF may be formed on the encapsulation layer TFE.

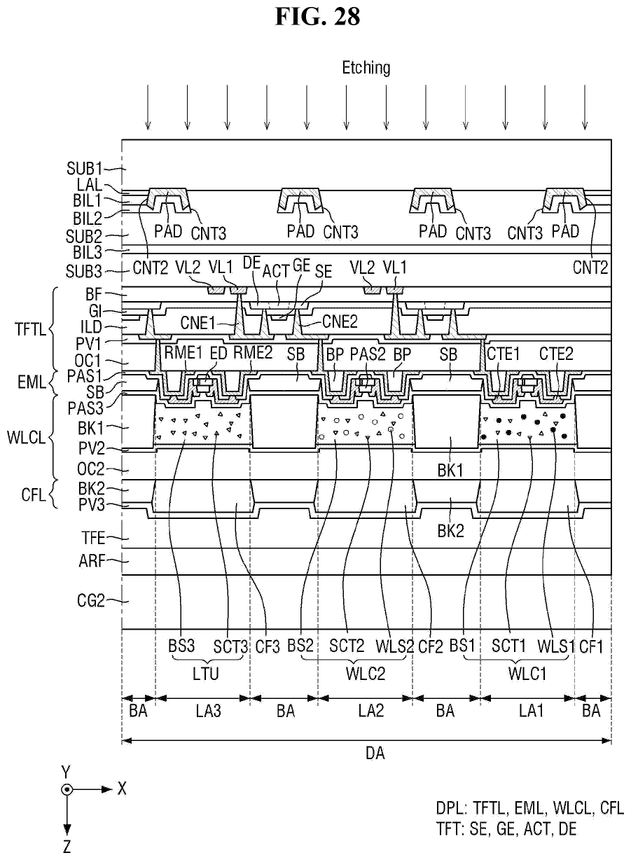

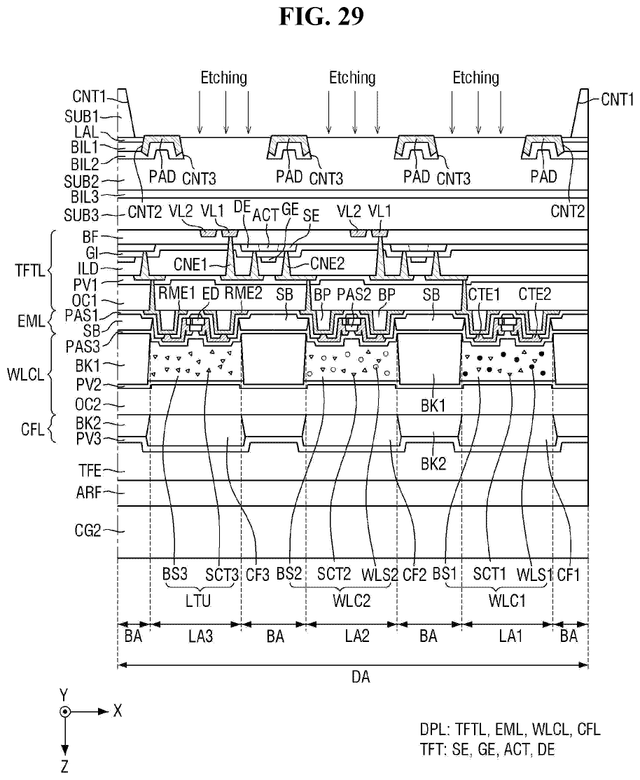

In FIGS. 28 and 29, the display device 10 being manufactured may be vertically inverted to attach the flexible film FPCB. The first carrier substrate CG1 may be removed from the first substrate SUB1. For example, the first carrier substrate CG1 may be removed from the bottom surface of the first substrate SUB1 using a sacrificial layer (not shown) disposed between the first carrier substrate CG1 and the first substrate SUB1, but the disclosure is not limited thereto.

A second carrier substrate CG2 may be disposed on a surface of the anti-reflection film ARF. The second carrier substrate CG2 may support the vertically inverted display device 10. For example, the second carrier substrate CG2 may be a carrier glass, but is not limited thereto.

A surface of the first substrate SUB1 may be subjected to at least one of a dry etching process, a plasma etching process, or a laser etching process. For example, a surface of the first substrate SUB1 may be patterned through a laser etching process. The laser absorption layer LAL may absorb an ultraviolet laser in the etching process of the first substrate SUB1 to prevent transmission of the ultraviolet laser. Here, the ultraviolet laser may have a wavelength of about 300 nm to about 400 nm, preferably, a wavelength of about 340 nm to about 350 nm. The laser absorption layer LAL or the pad portion PAD may prevent peeling between the second barrier insulating layer BIL2 and the second substrate SUB2 during the etching process of the first substrate SUB1 using ultraviolet laser. Since the second substrate SUB2 is integrally formed, the second substrate SUB2 inserted into the third contact hole CNT3 may not be peeled off during the etching process of the first substrate SUB1 using ultraviolet laser. Accordingly, the first contact hole CNT1 may be provided in the first substrate SUB1, and may expose the pad portions PAD, the laser absorption layer LAL, and the second substrate SUB2. A surface of the pad portion PAD may protrude from the laser absorption layer LAL, but the disclosure is not limited thereto.

For example, the laser absorption layer LAL may include amorphous silicon (a-Si). In case that the laser absorption layer LAL is exposed to ultraviolet laser, the laser absorption layer LAL may be crystallized to polysilicon (p-Si), and may have weak conductivity so that a microcurrent may flow. Accordingly, the second substrate SUB2 may be inserted into the third contact hole CNT3 to insulate adjacent pad portions PAD.

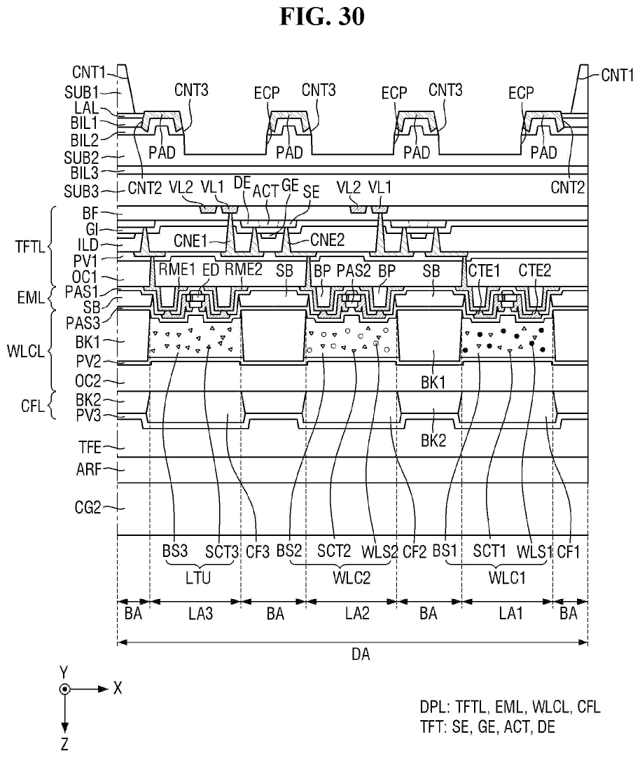

In FIG. 30, a surface of the second substrate SUB2 exposed by the first contact hole CNT1 may be subject to at least one of a dry etching process, a plasma etching process, or a laser etching process. For example, a surface of the second substrate SUB2 may be patterned through a laser etching process. Here, the ultraviolet laser may have a wavelength in a range of about 300 nm to about 400 nm, preferably, a wavelength in a range of about 340 nm to about 350 nm.

A part of the second substrate SUB2 may be etched to form the etched portion ECP. The pad portions PAD adjacent in the first direction (X-axis direction) may be spaced apart from each other with the etched portion ECP therebetween. The laser absorption layer LAL may not exist between the adjacent pad portions PAD. Since the second substrate SUB2 is integrally formed, the second substrate SUB2 including the etched portion ECP may not be peeled off during the etching process using ultraviolet laser.

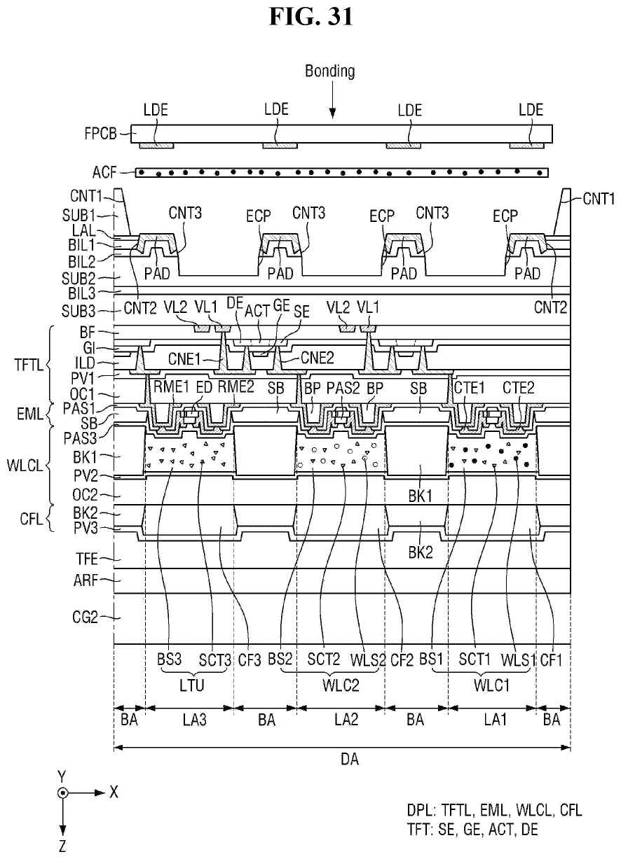

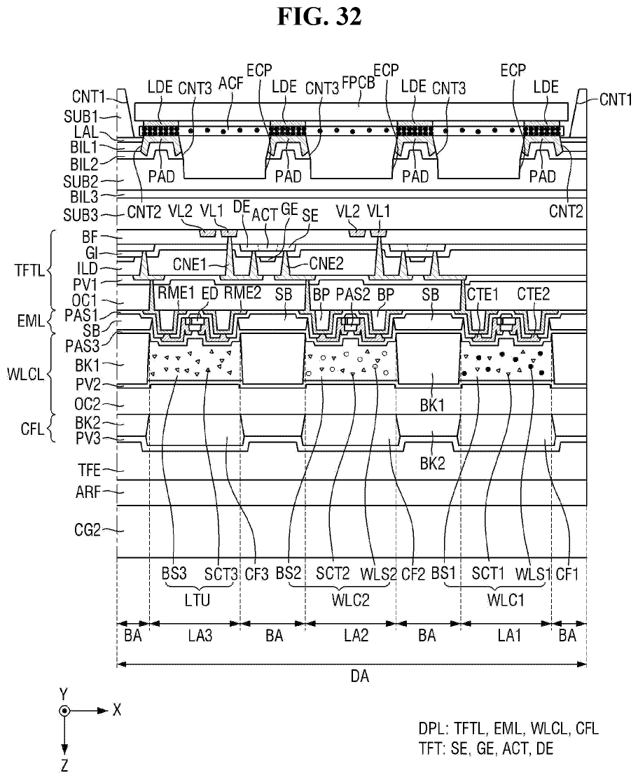

In FIGS. 31 and 32, the flexible film FPCB may be disposed on a surface of the first substrate SUB1. The flexible film FPCB and the lead electrode LDE may be aligned on the pad portion PAD through an alignment process. For example, the lead electrode LDE of the flexible film FPCB may be attached to the pad portion PAD through ultrasonic bonding or thermocompression bonding, but the bonding method is not limited thereto. The connection film ACF may have conductivity in a region where the pad portion PAD and the lead electrode LDE contact each other, and may electrically connect the flexible film FPCB to the pad portion PAD.

The second substrate SUB2 may include the etched portion ECP, and the laser absorption layer LAL and the first and second barrier insulating layers BIL1 and BIL2 that are disposed between the adjacent pad portions PAD are removed to expose the side surfaces of the pad portions PAD, so that a compression pressure or a bonding pressure may be concentrated on the protruding pad portion PAD during the bonding process of the pad portion PAD and the lead electrode LDE, and the conductivity of the connection film ACF may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate comprising a first contact hole;
a laser absorption layer disposed on the first substrate and containing amorphous silicon;
a first barrier insulating layer disposed on the laser absorption layer;
fan-out lines disposed in a metal layer on the first barrier insulating layer and comprising pad portions inserted into second contact holes provided in the first barrier insulating layer and the laser absorption layer;
a second barrier insulating layer disposed on the metal layer;
a second substrate disposed on the second barrier insulating layer; and
a display layer disposed on the second substrate,
wherein the second substrate is inserted into a third contact hole provided in the second barrier insulating layer, the first barrier insulating layer, and the laser absorption layer disposed between the pad portions.

2. The display device of claim 1, wherein the laser absorption layer disposed between adjacent pad portions among the pad portions is spaced apart from an adjacent laser absorption layer with the second substrate disposed between the laser absorption layer and the adjacent laser absorption layer.

3. The display device of claim 1, further comprising:
a flexible film disposed under the first substrate and inserted into the first contact hole to be electrically connected to the pad portions.

4. The display device of claim 3, further comprising:
a connection film inserted into the first contact hole to electrically connect the pad portions to the flexible film.

5. The display device of claim 4, wherein the second substrate is inserted into the third contact hole to face the connection film.

6. The display device of claim 3, further comprising:
a display driver disposed on the flexible film to supply at least one of a data voltage, a power voltage, and a gate signal.

7. The display device of claim 1, wherein the second substrate comprises an etched portion recessed from a surface of the laser absorption layer.

8. The display device of claim 7, wherein a depth of the etched portion is greater than a sum of thicknesses of the laser absorption layer, the first and second barrier insulating layers, and the pad portion.

9. The display device of claim 7, wherein the laser absorption layer disposed between adjacent pad portions among the pad portions is spaced apart from an adjacent laser absorption layer with the etched portion disposed between the laser absorption layer and the adjacent laser absorption layer.

10. The display device of claim 1, wherein
the display layer comprises a display area having pixels and a non-display area surrounding the display area, and
the pad portions and the third contact hole overlap the display area in a plan view.

11. The display device of claim 1, further comprising:
a third barrier insulating layer disposed between the second substrate and the display layer; and
a third substrate disposed between the third barrier insulating layer and the display layer.

12. A display device comprising:
a first substrate comprising a first contact hole;
a laser absorption layer disposed on the first substrate and containing amorphous silicon;
a first barrier insulating layer disposed on the laser absorption layer;
fan-out lines disposed in a metal layer on the first barrier insulating layer and comprising pad portions inserted into second contact holes provided in the first barrier insulating layer and the laser absorption layer;
a second barrier insulating layer disposed on the metal layer;
a third contact hole provided in the second barrier insulating layer, the first barrier insulating layer, and the laser absorption layer disposed between the pad portions;
a second substrate disposed on the second barrier insulating layer; and
a display layer disposed on the second substrate,
wherein the second substrate comprises an etched portion recessed from a surface of the laser absorption layer.

13. The display device of claim 12, wherein adjacent pad portions among the pad portions are spaced apart from each other with the etched portion disposed between the adjacent pad portions.

14. The display device of claim 12, wherein side surfaces of adjacent pad portions among the pad portions are exposed by the third contact hole.

15. The display device of claim 12, wherein the third contact hole has an undercut structure in which an upper area is smaller than a lower area of the third contact hole.

16. A method of manufacturing a display device, the method comprising:
providing a first substrate;
forming a laser absorption layer containing amorphous silicon on the first substrate;
forming a first barrier insulating layer on the laser absorption layer;
forming first contact holes penetrating the first barrier insulating layer and the laser absorption layer;
forming fan-out lines disposed on the first barrier insulating layer and comprising pad portions inserted into the first contact holes;
forming a second barrier insulating layer on the fan-out lines;
forming a second contact hole penetrating the second barrier insulating layer, the first barrier insulating layer, and the laser absorption layer disposed between the pad portions;
forming a second substrate on the second barrier insulating layer;
exposing the laser absorption layer, the pad portions, and the second substrate by etching the first substrate to form a third contact hole; and
inserting a flexible film into the third contact hole to electrically connect the flexible film to the pad portion.

17. The method of claim 16, further comprising:
after etching the first substrate to form the third contact hole, forming an etched portion by further etching the second substrate.

18. The method of claim 16, wherein the forming of the second contact hole comprises forming the second contact hole to have an undercut structure in which an upper area of the second contact hole is smaller than a lower area of the second contact hole.

19. The method of claim 18, further comprising:
after etching the first substrate to form the third contact hole, forming an etched portion by further etching the second substrate, and exposing side surfaces of adjacent pad portions among the pad portions.

20. A tiled display device comprising:
display devices each comprising a display area having pixels and a non-display area surrounding the display area; and
a bonding member configured to bond the display devices, wherein
at least one of the display devices comprises:
a first substrate comprising a first contact hole;
a laser absorption layer disposed on the first substrate and containing amorphous silicon;
a first barrier insulating layer disposed on the laser absorption layer;
fan-out lines disposed in a metal layer on the first barrier insulating layer and comprising pad portions inserted into second contact holes provided in the first barrier insulating layer and the laser absorption layer;
a second barrier insulating layer disposed on the metal layer;
a second substrate disposed on the second barrier insulating layer; and
a display layer disposed on the second substrate, and
the second substrate is inserted into a third contact hole provided in the second barrier insulating layer, the first barrier insulating layer, and the laser absorption layer disposed between the pad portions.
